(19) United States
(12) Patent Application Publication
(10) Pub. No.: US 2008/0122050 A1
(43) Pub. Date: May 29, 2008

(54) Semiconductor Device And Production Method For Semiconductor Device

(76) Inventors: Osamu Ikeda, Yokohama (JP); Masahide Okamoto, Yokohama (JP); Ryo Haruta, Tokyo (JP); Hidemasa Kagii, Tokyo (JP); Hiroi Oka, Tokyo (JP); Hiroyuki Nakamura, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/629,703

(22) PCT Filed: Jun. 15, 2005
(86) PCT No.: PCT/JP05/10921

§ 371 Date: Dec. 14, 2007

(30) Foreign Application Priority Data
Jun. 17, 2004 (JP) 2004-180071
Nov. 18, 2004 (JP) 2004-334629

(51) Int. Cl. H01L 23/495

(52) U.S. Cl. 257/669; 257/677; 257/E23.11

(57) ABSTRACT

A power semiconductor device in which a semiconductor element is die-mount-connected onto a lead frame in a Pb-free manner. In a die-mount-connection with a large difference of thermal expansion coefficient between a semiconductor element 1 and a lead frame 2, the connection is made with an intermetallic compound 200 having a melting point of 260° C. or higher or a Pb-free solder having a melting point of 260° C. or higher to 400° C. or lower, at the same time, the thermal stress produced in temperature cycles is buffered by a metal layer 100 having a melting point of 260° C. or higher. A Pb-free die-mount-connection which does not melt at the time of reflowing but have no chip crack to occur according to thermal stress can be achieved.

### TECHNICAL FIELD

The present invention relates to a semiconductor device technology including a power semiconductor device having a die-mount-connection part connected with the use of a Pb(lead)-free metal composite foil.

### BACKGROUND ART

A conventional power semiconductor device is shown in FIG. 1 wherein a power semiconductor element 1a is die-mount-connected onto a lead frame 2 by means a solder 3. After bonding the resulting product to leads 5 through wires 4, respectively, the bonded product is resin-molded with an epoxy-based resin 6. In this case, a high Pb solder and a solder to which trace amount of Ag or Cu are added to have a melting point (solidus temperature) of 290° C. or higher are used as the solder 3.

In the wire bonding process, there is a case where the temperature becomes 280° C. at the maximum. Furthermore, when a power semiconductor device is surface-mount soldered to a substrate, it is supposed that the power semiconductor is heated up to 260° C. at the highest in the case of reflow connection, since the melting point of a Sn—Ag—Cu based Pb free solder which will be used typically hereafter is high, i.e. about 220° C. Accordingly, a solder having a melting point of higher than 280° C., i.e. the above-mentioned high Pb solder is used in such that the solder 3 does not remelt in the case of wire bonding and in the case of reflowing.

In the case of wire bonding, when the solder is remelted, the wire bonding becomes impossible. Although the solder-connected part of the power semiconductor element 1a and the lead frame 2 has been resin-molded with the epoxy-based resin 6, when the solder 3 inside the resin mold remelts, there arises a case where the solder 3 existing inside the resin mold leaks out from the interface of the epoxy-based resin 6 and the lead frame 2, because of the cubical expansion due to the melting phenomenon which is called by the name of “flash” as shown in FIG. 2. Even if the solder 3 did not leak out, it behaves to leak out so that large voids are formed in the solder 3 after the solidification thereof, whereby it causes the device to be defective.

The soldered portion of the die-mount-connected part does not mean only for fixing the power semiconductor element 1a to the lead frame 2, but it functions as a path for escaping the heat of the power semiconductor element 1a to the lead frame 2 side. For this reason, when the voids and the like are formed due to remelting of the solder 3 as described above, it becomes that diffusion of the heat is not sufficiently performed through the connection part, resulting in functional deterioration of the power semiconductor element 1a.

As a result of decision of the enforcement of ROHS Directive (the restriction of the use of certain hazardous substances in electrical and electronic equipment) by EU dated Jul. 1, 2006, a project for making solder for connection with respect to a substrate to be lead-free advances rapidly with focusing on Sn—Ag—Cu based Pb-free solders.

On the other hand, die-mount-connection wherein a high Pb solder has been used heretofore is excluded from the object of the above-mentioned restriction because no technical solution as to a replaceable solder of a Pb-free solder is not found. It is, however, desired to make also such high Pb solder to be Pb-free in view of reduction of environmental burdens.

However, in the Pb-free solder to be used in a die-mount-connection part, it is required to have a high melting point at which the Pb-free solder does not remelt in the case of wire bonding or in the case of reflowing in board-mounting as mentioned above. Concerning wire bonding, it is possible to change the wire bonding to a bonding at a low temperature such as ultrasonic bonding of Al at a room temperature. However, reflow soldering on the substrate to which a Sn—Ag—Cu-based Pb-free solder is applied is an unavoidable process, so that it is required to make a melting point of the solder 3 to be at least 260° C. or higher.

Among Sn-based Pb-free solders, there are Sn—Sb-based solders (a melting point of 232 to 240° C.) as those having comparatively high melting points. However, even in such melting points, they are too low so that they cannot be applied because of remelting in the post-process.

In addition, Au-20Sn (melting point: 280° C.) is well known as a Pb-free high-melting point solder. However, since it contains 80% of Au, it is expensive so that it is difficult to apply to inexpensive electronic parts from the viewpoint of the cost. Furthermore, since the Au-20Sn solder is a hard solder having rigidity, there is a fear of damaging the power semiconductor element or the connection part, resulting in a problem of connection reliability in such a case where the following condition for application of the Au-20Sn solder wherein thermal fatigue are experienced repeatedly under an insufficient stress buffering function is supposed for applying to die-mount connection wherein the connection is made in a comparatively large area in a combination of presenting such a large thermal expansion coefficient difference in the power semiconductor element (Si) and a Cu-based frame.

Such problems of the connection reliability may be improved by increasing the solder supply, but on the other hand, the increased supply results in a further expensive cost, whereby a problem of profitability arises.

On the other hand, such a challenge that the connection part is made to be an alloy in the case of realizing a Pb-free state of the connection part is reported in non-patent document 1.

Namely, it is reported that the GaAs the rear surface thereof is metallized with Cr (0.03 μm)/Sn (2.5 μm)/Cu (0.1 μm) is connected with a substrate (glass) metallized with Cr (0.03 μm)/Cu (4.4 μm)/Au (0.1 μm) at 280° C., and then, it is maintained for 16 hours, whereby the connection part is made to be substantially Cu₃Sn compound, so that it becomes possible to make the connection part to have a high melting point.

Likewise, it is reported that the Si the rear surface thereof is metallized with Cr (0.03 μm)/In (3.0 μm)/Ag (0.5 μm) is connected with the Si metallized with Cr (0.03 μm)/Au (0.05 μm)/Ag (5.5 μm)/Au (0.05 μm) at 210° C., and then, it is subjected to aging treatment at 150° C. for 24 hours, whereby the connection part is made to be Ag-rich alloy+Ag₃In, so that it becomes possible to make the connection part to have a high melting point.

In non-patent document 2, it is reported below in such that Ni-xCo (x=0.10) metallized with Sn-3.5Ag (26 μm) and a product obtained by the covar metallized with Ni-20Co (5 μm) further metallized with Au (1 μm) are connected at 240° C. in such that they are fit together; and they are maintained for 30 minutes, whereby the whole connection part is made to be a (Ni, Co)Sn₂+(Ni, Co)₃Sn₄ compound, so that it becomes possible to make the connection part to have a high melting point. In this case, growth rate of the compound is accelerated by using the Ni-20Co containing Co for the metallization.

In these methods, when the connection part was once made completely to have a high melting point, the connection part is not remelted, but it is possible to hold the connection, even if the connection part is heated up to 260° C. in the case of reflow soldering.

Non-patent document 1: Williams W. So et al., “High Temperature Joints Manufactured at Low Temperature”, Proceeding of ECTC; 1998, p 284.

Non-patent document 2: Yamamoto et al., “Study for making micro-connection part using Sn—Ag solder to be intermetallic compound”, Collection of Brief Summary of MES 2003; October 2003, p 45.

### DISCLOSURE OF THE INVENTION

The present inventors considered that the technologies for making a material to have a high melting point described in the non-patent documents 1 and 2 may be applied to obtain a Pb-free condition in a die-mount-connection part. In the above-described two prior arts, however, there is no consideration as to the following points, so that it is difficult to apply the above-described technologies to the die-mount-connection part where is required to have high connection reliability for realizing an important function as a heat dissipation path for a power semiconductor element.

More specifically, according to the connection methods of Williams W. So et al. as well as Yamamoto et al., the connection part is made to be a compound so as to achieve a high melting point. As a result, the connection part becomes rigid and brittle as compared with the existing high Pb solder. In this respect, however, the connection is conducted in the combination of materials having a small difference in the coefficients of thermal expansion in both the non-patent documents 1 and 2. Accordingly, there is no consideration as to the damages and the like in the case where thermal fatigue is inflicted to the materials due to the brittleness accompanied with such modification for achieving realization of a high melting point.

In the case where the technologies of the non-patent documents 1 and 2 are applied to the junction of the combination of the power semiconductor element (Si) being the object of the present invention and a Cu-based lead frame exhibiting a large thermal expansion coefficient difference, the hard and brittle connection part as shown in the non-patent documents 1 and 2 cannot buffer the thermal stress produced in temperature cycles, resulting in a large load with respect to the chip thereby to cause chip cracks, and thus, the connection reliability cannot be assured.

Although it may be considered that a thickness of the connection part is increased as the measure for improving the prevention of chip cracks, the thickened connection part brings about a very long period of time for achieving a complete compound. In this respect, it is possible to increase the connection temperature thereby to make faster the growth rate of the compound, so that the time required for achieving the complete compound can be reduced. In this case, however, the remaining stress after the connection becomes large, and hence, it becomes a cause for generating chip cracks.

As mentioned above, the technologies for achieving a high melting point described in the non-patent documents 1 and 2 cannot satisfy required specifications in the die-mount-connection part in the existing condition. Accordingly, it cannot be intended to apply the Pb-free technology to such die-mount-connection part as long as the problems of such connection reliability are not solved.

An object of the present invention is to realize a Pb-free junction wherein the connection may be maintained in the materials to be joined such as a semiconductor element (Si) and a Cu-based lead frame which exhibit a large thermal expansion coefficient difference thereof at even the highest temperature supposed to be in the case of reflowing, and by which the connection reliability causing no damage on the semiconductor element with respect to thermal stress to the connection part can be assured.

Another object of the invention is to provide a Pb-free semiconductor device by which the connection can be maintained in the case of reflowing at 260° C., and good connection reliability can be attained in the combination of materials such as a semiconductor element (Si) and a Cu-based lead frame which exhibit a large thermal expansion coefficient difference of them even in the case where die-mount-connection is conducted over a comparatively large area.

In order to solve the above-described problems, the present first invention provides a semiconductor device wherein a semiconductor element is die-mount-connected onto a lead frame by means of a metal joint, characterized in that the metal joint includes a stress buffering layer for buffering thermal stress produced due to a thermal expansion coefficient difference between the lead frame and the semiconductor element; a connection layer formed on the semiconductor element side of the stress buffering layer and for connecting the stress buffering layer with the semiconductor element; and another connection layer formed on the lead frame side of the stress buffering layer and for connecting the stress buffering layer with the lead frame.

The chip cracks appeared on the semiconductor element side in the die-mount joint section is due to such fact that since a thermal expansion coefficient difference between the lead frame to be jointed and the semiconductor element is large, the semiconductor element side cannot expand and contract in response to that of the lead frame side having a high thermal expansion coefficient. In this respect, when the stress buffering layer as described above is provided, the stress due to thermal expansion and contraction can be absorbed by the stress buffering layer, whereby such stress is not transmitted to the semiconductor element side, so that any chip crack does not appear.

A present second invention provides the semiconductor device as described in the first invention, characterized in that the connection layer is a metal layer or an intermetallic compound layer having a melting point of 260° C. or higher; and the stress buffering layer is a metal layer having a thermal expansion coefficient ranging from the thermal expansion coefficient of the semiconductor element to the thermal expansion coefficient of the lead frame. When the thermal expansion coefficient of the metal layer constituting the stress buffering layer is set out as in the second invention, the stress derived from the lead frame side may be buffered.

A present third invention provides the semiconductor device as described in the first invention, characterized in that the connection layer is a metal layer or an intermetallic compound layer having a melting point of 260° C. or higher; and the stress buffering layer is a metal layer having an yield stress of less than 100 MPa. When the yield stress of the metal layer constituting the stress buffering layer is set out as in the third invention, the stress derived from the lead frame side may be buffered.

A present fourth invention provides the semiconductor device as described in the first invention, characterized in that the connection layer formed on the semiconductor element side of the stress buffering layer is made of a Pb-free solder layer, for example, an Au—Sn-based alloy, an Au—Ge-based alloy, an Au—Si-based alloy, a Zn—Al-based alloy, a Zn—Al—Ge-based alloy, Bi, a Bi—Ag-based alloy, a Bi—Cu-based alloy, a Bi—Ag—Cu-based alloy or the like, having a melting point of 260° C. or higher to 400° C. or lower; and the connection layer formed on the lead frame side of the stress buffering layer is made of a Pb-free solder layer having a melting point of 260° C. or higher to 400° C. or lower, lower than that of the connection layer formed on the semiconductor element side of the stress buffering layer.

As mentioned above, the chip cracks appeared on the semiconductor element side in the die-mount joint section is due to such fact that since a thermal expansion coefficient difference between the lead frame to be joined and the semiconductor element is large, the semiconductor element side cannot expand and contract in response to that of the lead frame side having a high thermal expansion coefficient. It may be considered to be possible to suppress such chip crack by increasing a thickness of the metal joint section. In this respect, however, there arises such a problem that an Au-20Sn solder is expensive in the case of the connection with a single material, while sufficient heat dissipation cannot be made by a Bi-based solder because the thermal conductivity thereof is 9 W/m·K being as low as about ⅓ of a high Pb solder. On the other hand, when the metal joint section is made to be a complete compound, the joint section becomes rigid and brittle, besides considerable time is required for achieving the complete compound, so that there arises such a problem that the technology mentioned herein is difficult to apply industrially from the viewpoint of production efficiency.

Accordingly, when the stress buffering layer is provided as mentioned above, the metal joint section may be thickened with the stress buffering layer and the connection layer itself may be thinned. As a result, an amount of the Au-20Sn to be applied can be reduced by the amount corresponding to the thinned layer, resulting in easier heat dissipation with the Bi-based solder having a low thermal conductivity in a degree corresponding to the thinned layer, so that an amount of a rigid and brittle intermetallic compound may be reduced.

Thus, it becomes possible to join materials having a thermal expansion coefficient difference to each other without accompanying any chip crack within a range wherein a difference of coefficients of thermal expansion extends from a small difference of, for example, about 4 ppm/° C. as in the case of between Si and a ceramic substrate to a large difference of about 14 ppm/° C. as in the case of between Si and Cu as a result of providing the stress buffering layer.

The reason for employing a Pb-free solder having a melting point of 260° C. or higher to 400° C. or lower in the forth invention is in that there are such a problem that a solder is remelted in the case of reflow soldering, when the melting point of the solder is 260° C. or lower, and such a problem that a Cu-based frame becomes softened to be deformed in the case of the die-mount-connection, when the melting point of the solder is 400° C. or higher.

Furthermore, since it is possible to buffer thermal stress by means of the stress buffering layer, the reliability may be assured even in a case where the above-described Pb-free solder is thinly applied. Hence, it becomes possible to reduce an amount of a solder to be applied even in a case where an expensive Au-based solder is used. In this case, a thickness of a solder for the connection is preferably 1 μm or more. When it is less than 1 μm, the wettability over the whole region of the interface cannot be assured in the case of the connection, and there may be a case of poor connection.

In order to form connection layers on the semiconductor element side and the lead frame side of the stress buffering layer, respectively, it may apply, for instance, a composite foil containing metal layers which form the connection layers by heating at the time of die-mount-connection on a metal layer having stress buffering function. As a result of providing a temperature stratum in the melting point of the connection layer on the front and rear surfaces thereof, when the composite foil is supplied to the lead frame at a temperature at which only the connection layer formed on the lead frame side of the stress buffering layer and a pressurizing step as well as a scrubbing step are applied from the side of the non-melting connection layer formed on the semiconductor element side of the stress buffering layer, the connectability and the void evacuatability can be improved in the connection part for composite foil and lead frame. In addition, when the pressurizing and scrubbing steps are applied in the case of supplying the semiconductor element, the connectability and the void evacuatability can be improved in the semiconductor element and composite foil connection part as well.

A present fifth invention provides the semiconductor device as described in the first invention, characterized in that the connection layer formed on the semiconductor element side of the stress buffering layer is made of a Pb-free solder layer, for example, an Au—Sn-based alloy, an Au—Ge-based alloy, an Au—Si-based alloy, a Zn—Al-based alloy, a Zn—Al—Ge-based alloy, Bi, a Bi—Ag-based alloy, a Bi—Cu-based alloy, a Bi—Ag—Cu-based alloy or the like, having a melting point of 260° C. or higher to 400° C. or lower; and the connection layer formed on the lead frame side of the stress buffering layer is made of an intermetallic compound layer having a melting point of 260° C. or higher and formed by the reaction of at least one of Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based and the like Pb-free solders with at least one metal of Cu, Ag, Ni, and Au in the case of the die-mount-connection.

In the case of die-mount-connection, when the connection is conducted at a temperature of 400° C. or higher, a Cu-based frame is softened, so that it is necessary for conducting the connection at a temperature of 400° C. or lower. Each of the Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based and the like Pb-free solders to form the connection layer made on the lead frame side of the stress buffering layer has a melting point of 260° C. or lower. Accordingly, when any one of the above-described Pb-free solders is used alone for the connection, the solder remelts in the case of reflow soldering, whereby the connection cannot be maintained due to solder flash and exfoliation in the connection interface.

Hence, it is necessary for making the melting point after the connection to have a high melting point of 260° C. or higher as a result of the formation of a metal compound through the reaction of such a metal of Cu, Ag, Ni, or Au which reacts with any one of the Pb-free solders of Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based and the like. In this case, a thickness of the intermetallic compound layer in the connection part is preferably 1 to 30 μm. When it is less than 1 μm, there may be a case where wettability cannot be assured over the whole region of the connection interface at the time of the connection, whereby poor connection arises. On the other hand, when the thickness is more than 30 μm, there may be a case where a long period of time is required for achieving the complete compound of the connection part so that the productivity becomes poor. In addition, since the connection is possible at a temperature of 260° C. or lower, the residual stress appearing at the time of cooling after the die-mount-connection can be reduced.

As a result of providing a temperature stratum in the melting point of the solder forming the connection layer on the front and rear surfaces of the composite foil, when the composite foil is supplied to the lead frame at a temperature at which only the connection layer formed on the lead frame side of the stress buffering layer and a pressurizing step as well as a scrubbing step are applied from the side of the unmelted connection layer formed on the semiconductor element side of the stress buffering layer, the connectability and the void evacuatability can be improved in the connection part for composite foil and lead frame. In addition, when the pressurizing and scrubbing steps are applied in the case of supplying the semiconductor element, the connectability and the void evacuatability can be improved also in the connection part for the semiconductor element and composite foil. In this case, it is desired that the lead frame is connected with the composite foil by means of a compound even which is locally formed in the connection layer formed on the lead frame side of the stress buffering layer.

A present sixth invention provides the semiconductor device as described in the first invention, characterized in that the connection layer formed on the semiconductor element side of the stress buffering layer is made of an intermetallic compound layer having a melting point of 260° C. or higher and formed by the reaction of one of Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based and the like Pb-free solders each having a melting point of 260° C. or lower with at least one metal of Cu, Ag, Ni, and Au in the case of the die-mount-connection; and the connection layer formed on the lead frame side of the stress buffering layer is made of an intermetallic compound layer having a melting point of 260° C. or higher and formed by the reaction of one of Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based and the like Pb-free solders each having a lower melting point than that of the Pb-free solder forming the connection layer formed on the semiconductor element side of the stress buffering layer with at least one metal of Cu, Ag, Ni, and Au in the case of the die-mount-connection.

In the case of die-mount-connection, when the connection is conducted at a temperature of 400° C. or higher, a Cu-based frame is softened, so that it is necessary for conducting the connection at a temperature of 400° C. or lower. Each of the Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based and the like Pb-free solders has a melting point of 260° C. or lower. Accordingly, when any one of the above-described Pb-free solders is used alone for the connection, the solder remelts in the case of reflow soldering, whereby the connection cannot be maintained due to solder flash and exfoliation in the connection interface.

Hence, it is necessary for making the melting point after the connection to have a high melting point of 260° C. or higher as a result of the formation of a metal compound through the reaction of such a metal of Cu, Ag, Ni, or Au which reacts with any of the Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based and the like Pb-free solders.

In this case, a thickness of the intermetallic compound layer in the connection part is preferably 1 to 30 μm. When it is less than 1 μm, there may be a case where wettability cannot be assured over the whole region of the connection interface at the time of the connection, whereby poor connection arises. On the other hand, when the thickness is more than 30 μm, there may be a case where a long period of time is required for achieving the complete compound of the connection part so that the productivity is lowered. Besides, since the connection is possible to be made at a temperature of 260° C. or lower, the residual stress appearing at the time of cooling after the die-mount-connection can be reduced.

As a result of providing a temperature stratum in the connection layer on the front and rear surfaces of the composite foil, when the composite foil is supplied to the lead frame at a temperature at which only the connection layer formed on the lead frame side of the stress buffering layer and a pressurizing step as well as a scrubbing step are applied from the side of the unmelted connection layer formed on the semiconductor element side of the stress buffering layer, the connectability and the void evacuatability can be improved in the connection part for the composite foil and lead frame. In addition, when the pressurizing and scrubbing steps are applied in the case of supplying the semiconductor element, the connectability and the void evacuatability can be improved also in the connection part for the semiconductor element and composite foil. In this case, it is desired that the lead frame is connected with the composite foil by means of a compound even which is locally formed in the connection layer formed on the lead frame side of the stress buffering layer.

A present seventh invention provides a semiconductor device wherein a semiconductor element is die-mount-connected onto a lead frame by means of a metal joint, characterized in that the metal joint contains an unreacted high melting point metal which does not react in the case of the die-mount-connection; and an intermetallic compound formed by the reaction in the case of joining the high melting point metal to the semiconductor element as well as joining the high melting point metal to the lead frame.

The above-described constitution may be effectively applied to the case where such chip cracks appearing at a high possibility of, for example, 6/20 or the like in a conventional metal joint wherein there is a thermal expansion coefficient difference of, for example, 5 ppm/° C. or higher between the semiconductor element and the lead frame which has been proposed heretofore and such chip cracks of which could not have been eliminated.

As mentioned above in the description of the present first invention, the chip cracks appeared on the semiconductor element side in the die-mount joint section is due to such fact that since a thermal expansion coefficient difference between the lead frame and the semiconductor element to be joined is large, the semiconductor element side cannot expand and contract in response to that of the lead frame side having a high thermal expansion coefficient. It may be considered in this respect to be possible to suppress such chip crack by increasing a thickness of the metal joint section. In this connection, however, there arises such a problem that an Au-20Sn solder is expensive in the case of the connection with a single material, while sufficient heat dissipation cannot be made by a Bi-based solder because the thermal expansion coefficient thereof is 9 W/m·K being as low as about ⅓ of a high Pb solder. On the other hand, when the metal joint section is made to be a complete compound, the joint section becomes rigid and brittle, besides considerable time is required for achieving the complete compound, whereby it is pointed out to involve such a problem that the technology mentioned herein is industrially inappropriate.

Accordingly, when the stress buffering layer is provided as mentioned above, the metal joint section may be thickened with the stress buffering layer and the connection layer itself may be thinned. As a result, an amount of the Au-20Sn to be applied can be reduced, resulting in heat dissipation with the Bi-based solder having a low thermal expansion coefficient, so that an amount of a rigid and brittle intermetallic compound may be reduced. Thus, it becomes possible to appear no chip crack within a range wherein a difference of coefficients of thermal expansion extends from a small difference of, for example, about 4 ppm/° C. as in the case of Si and a ceramic substrate to a large difference of about 14 ppm/° C. as in the case of Si and Cu as a result of providing the stress buffering layer.

Under the circumstances, the present inventors considered to utilize a high melting point metal used for an intermetallic compound in the constitution of the stress buffering layer. Heretofore, such constitution has not been practically applied, because there was appearance of chip cracks in the thermal cycle tests after the connection due to the rigid and brittle natures of the intermetallic compound in the case where the whole metal joint for connecting the semiconductor element with the lead frame wherein a thermal expansion coefficient difference is 5 ppm/° C. or more is made from an intermetallic compound formed by the reaction with a high melting point metal in the case of joining the semiconductor element to the lead frame.

As in the present invention, however, either such an arrangement that a remaining part in an unreacted state is prepared purposely in the high melting point metal used in the case of forming the intermetallic compound, or such an arrangement that a high melting point metal layer which does not react with the intermetallic compound is separately provided was previously prepared. As a result, such unreacted part of the high melting point metal as described above may function as a stress buffering layer, so that such stress derived from the rigid and brittle nature of intermetallic compound and which leads appearance of chip cracks which could not have been avoided in the intermetallic compound comes to be possible to avoid by the stress buffering layer involving such unreacted high melting point metal.

In also the experiments, it is confirmed that when a layer of such unreacted high melting point metal is provided in the case of joining a semiconductor element to a lead frame wherein there is a thermal expansion coefficient difference of 5 ppm/° C. between the semiconductor element and the lead frame, the constitution of the intermetallic compound can be applied. In the layer of such unreacted high melting point metal, either of the metals used in the case of forming the intermetallic compound concerned with the joint structure of the actual semiconductor element and the lead frame, or the metals, which are not concerned with the formation of such intermetallic compound, may be applied.

According to the constitution as mentioned above, when a temperature cycle test of 500 cycles of −55° C.(30 min.)/150° C.(30 min.) was implemented with respect to twenty packages prepared by joining the semiconductor element to the lead frame, it became possible that no chip crack appeared in all cases.

It is very important to provide an unreacted metal layer having a high melting point which does not react in a joint condition at the time of die-mount-connection in the metal joint section without constituting the metal joint by means of the complete compound. Even in the prior art documents 1 and 2 wherein there is an idea of joint in the intermetallic compound, neither any description nor a suggestion, inclusive, is not found with respect to such an unreacted high melting point metal layer. Accordingly, this is the unique conception involved in the invention itself of the present application.

A present eighth invention provides a semiconductor device having a semiconductor element, and a substrate connected to the semiconductor element, characterized in that the semiconductor element is connected with the substrate through a metal containing layer containing a metal and an intermetallic compound layer being thinner than the metal containing layer and including the metal component contained in the metal containing layer; and the connection between the semiconductor element and the substrate does not melt even at the upper temperature limit of the semiconductor device.

A present ninth invention provides a semiconductor device having a semiconductor element, and a lead frame connected to the semiconductor element through a connection part, characterized in that the connection part has a metal containing layer containing a metal and an intermetallic compound layer being thinner than the metal containing layer and including the metal component contained in the metal containing layer; and the connection part does not melt even at the heat-resistant upper limit of the semiconductor device.

As shown in the above-described constitution, the semiconductor element such as a semiconductor chip is connected with a substrate such as the lead frame through the metal containing layer and the intermetallic compound having a metal component contained in the metal containing layer in the present eighth and ninth inventions. Accordingly, a layer thickness of the intermetallic compound may be decreased as compared with a case where such a connection part is constituted by a single layer made of only intermetallic compound.

An intermetallic compound has a nature of a high allowable temperature limit, but it is rigid and brittle. And so when the intermetallic compound is used for the connection of the semiconductor element with a substrate as a single layer, to avoid effects such as appearance of the thermal stress produced in temperature cycles when it is used on the side of a semiconductor element, the thickness of the layer is made to be thick to expect its buffering action in the thickness direction.

In the above-described present invention, however, since a layer of the intermetallic compound is applied as a multiple layer including a metal containing layer, it is possible to design an intermetallic compound layer thin unlike the case where the intermetallic compound is applied as a single layer. Accordingly, when the metal containing layer is allowed to take on stress buffering function, it becomes unnecessary that the intermetallic compound layer does not take on such stress buffering function exclusively, whereby the intermetallic compound layer may be thinner than that of the metal containing layer. Thus, it becomes possible to assure the connection between the semiconductor element and the substrate while buffering the thermal stress due to the fact that the semiconductor element side cannot expand and contract in response to the expanding and contraction in the substrate side including the lead frame and the like having a large thermal expansion coefficient even when there is a large thermal expansion coefficient difference between the substrate such as the lead frame and the semiconductor element such as a semiconductor chip. In other word, for example, the intermetallic layer bends easily to follow the distortion as much as the intermetallic compound layer may be thinned, so that it is advantageous from the viewpoint of buffering thermal stress as compared with the case where the layer thickness is thick.

When a layer thickness of such intermetallic compound layer is considered from a relationship of a connection area of the semiconductor element and the substrate, it is required to apply the intermetallic compound with a thickened connection part in the case where both the connection areas of the semiconductor element and the substrate to be connected are the same with each other, if the semiconductor element is connected with the substrate by means of a single layer of the intermetallic compound, since the intermetallic compound has a high allowable temperature limit but is rigid and brittle as described above. In the present invention, however, since the intermetallic compound may be constituted in the form of a multiple layer including a metal containing layer by which stress buffering function is taken on as described above, a layer thickness thereof may be decreased within a range wherein connection reliability can be assured. Furthermore, the thinner layer thickness results in the less effects of stress.

A present tenth invention provides a semiconductor device wherein a semiconductor element is die-mount-connected onto a lead frame, then, the resulting product is subjected to wire-bonding, and resin-molding, characterized in that the die-mount-connected part is successively consist of, from the semiconductor element side, an intermetallic compound layer having a melting point of 260° C. or higher, a metallic compound layer having a melting point of 260° C. or higher, and another intermetallic compound layer having a melting point of 260° C. or higher in this order.

The highest temperature is 260° C. in the case of reflow soldering of a semiconductor package onto a substrate, so that it is required that a melting point of the connection part is 260° C. or higher after the connection in order to maintain the connection at the time of the reflow soldering.

An intermetallic compound layer having a melting point of 260° C. or higher is formed, for example, in the reaction of a solder having a melting point of 260° C. or lower with a metal having a melting point of 260° C. or higher. In the case of the connection, the wettability is assured by the solder having a melting point of 260° C. or lower. At the same time, the solder having a melting point of 260° C. or lower is allowed to react with the metal having a melting point of 260° C. or higher, whereby an intermetallic compound is formed to make the connection part to have a high melting point. In this case, since it is possible to conduct the connection at a temperature of 260° C. or lower, it becomes possible to reduce the residual stress appeared in the case of cooling after the die-mount-connection.

The metal layer having a melting point of 260° C. or higher is used for buffering thermal stress. In the case where the connection part after the connection is only made from the intermetallic compound, the connection part becomes rigid and brittle, so that the connection reliability is remarkably damaged by chip cracks and cracks progress rapidly in the intermetallic compound. Hence, a metal layer, which can buffer a stress, is provided in the connection part, whereby the thermal stress produced in the case of temperature cycles and cooling after the connection is buffered to suppress the appearance of cracks thereby assuring the reliability.

Thus, the connection reliability can be assured in both cases of the connection with a large thermal expansion coefficient difference between a semiconductor element and a Cu-based lead frame and the connection with a small thermal expansion coefficient difference between the semiconductor element and a 42-alloy lead frame.

A present eleventh invention provides the semiconductor device as described in the tenth invention, characterized in that the intermetallic compound layer is formed by the reaction of at least one of Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, and Bi—In-based Pb-free solders with at least one metal of Cu, Ag, Ni, and Au in the case of the die-mount-connection.

In the case of die-mount-connection, when the connection is executed at a temperature of 400° C. or higher, a Cu-based frame is softened, and hence, it is required to execute the connection at a temperature of 400° C. or lower. The Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, and Bi—In-based Pb-free solders have a melting point of 260° C. or lower. Accordingly, when they are applied alone for the connection, the solder is remelted in the case of reflow soldering, and accordingly, the connection cannot be maintained due to appearance of solder flash and exfoliation in the connection interface.

Under the circumstances, it is necessary to make the melting point after the connection high, to have a melting point of 260° C. or higher through the reaction wherein a metal such as Cu, Ag, Ni, or Au which reacts with the Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, and Bi—In-based Pb-free solders to form a metal compound. In this case, a thickness of the intermetallic compound layer in the connection part is preferably 1 to 30 μm. When it is less than 1 μm, the wettability over the whole region of the connection interface at the time of connection cannot be assured, so that there is a case where poor connection appears. On the other hand, when the thickness is more than 30 μm, a long period of time is required for achieving the complete compound of the connection part, so that there is a case where the productivity thereof becomes poor. In addition, since it is possible to make the connection at a temperature of 260° C. or lower, it is possible to reduce a residual stress at the time of cooling after the die-mount-connection.

A present twelfth invention provides a semiconductor device wherein a semiconductor element is die-mount-connected onto a lead frame, then, the resulting product is subjected to wire-bonding, and resin-molding, characterized in that the die-mount-connected part is successively consist of, from the semiconductor element side, a Pb-free solder layer having a melting point of 260° C. or higher to 400° C. or lower, a metallic compound layer having a melting point of 260° C. or higher, and another Pb-free solder layer having a melting point of 260° C. or higher to 400° C. or lower, in this order.

The connection is made by using a Pb-free solder having a melting point of 260° C. or higher to 400° C. or lower. The reason for making the solder to have a melting point of 260° C. or higher is in that the solder is not remelted in the case of reflow soldering. On the other hand, the reason for making the solder to have a melting point of 400° C. or lower is in that there is such a problem that when the die-mount-connection is conducted at a temperature of 400° C. or higher, the Cu-based frame becomes softened to be deformed.

The reason for providing a metal layer having a melting point of 260° C. or higher is in that the thermal stress produced by temperature cycles and cooling after the connection is to be buffered thereby suppressing appearance of chip cracks. As a result of providing the metal layer, the connection reliability can be assured in both cases of the connection with a large thermal expansion coefficient difference between a semiconductor element and a Cu-based lead frame and the connection with a small thermal expansion coefficient difference between the semiconductor element and a 42-alloy lead frame.

A present thirteenth invention provides the semiconductor device as described in the twelfth invention, characterized in that the Pb-free solder layer having a melting point of 260° C. or higher to 400° C. or lower is made of at least any one of Au—Sn-based alloy, Au—Ge-based alloy, Au—Si-based alloy, Zn—Al-based alloy, Zn—Al—Ge-based alloy, Bi, Bi—Ag-based alloy, Bi—Cu-based alloy, and Bi—Ag—Cu-based alloy.

The reason why a Pb-free solder having a melting point of 260° C. or higher to 400° C. or lower is used is in that when a melting point of the solder is 260° C. or lower, there is such a problem that the solder is remelted in the case of reflow soldering, while when the melting point is 400° C. or higher, there is such a problem that a Cu-based frame becomes softened at the time of the die-mount-connection, resulting in deformation.

Since it is possible to buffer thermal stress by means of a metal layer, the reliability can be assured even in the case where the above-described Pb-free solder is thinned. As a result, usage of the solder may be reduced even in the case of using an expensive Au-based solder. In this case, a thickness in the connection of such solder is preferably 1 μm or more. When it is less than 1 μm, the wettability in the whole region of the connection interface cannot be assured in the case of the connection, whereby resulting in poor connection.

A present fourteenth invention provides the semiconductor device as described in the tenth to thirteenth inventions, characterized in that the metal layer having a melting point of 260° C. or higher is made of any one of Al, Mg, Ag, Zn, Cu, and Ni.

Al, Mg, Ag, Zn, Cu, and Ni has a smaller yield stress than that of an Au-20Sn which is a hard solder, so that it is easily subjected to plastic deformation. In this respect, thermal stress is buffered as a result of plastic deformation of Al, Mg, Ag, Zn, Cu, or Ni. In this case, it is desired that a magnitude of yield stress of the metal layer is 75 MPa or less as shown in FIG. 3. When the yield stress is 100 MPa or more, the thermal stress cannot sufficiently be buffered, so that the stress appeared in a semiconductor element becomes large, whereby there is a case where chip cracks appear. Although it does not mainly depend on the Young's modulus of a material to be used, but the smaller value is the more preferred. Moreover, a thickness thereof is preferably 30 to 200 μm. When the thickness is less than 30 μm, the thermal stress cannot be sufficiently buffered, so that there is a case where chip cracks appear. On the other hand, when the thickness is 200 μm or more, the effect of thermal expansion coefficient increases, because Al, Mg, Ag, or Zn has a larger thermal expansion coefficient than that of the Cu-frame, and as a result, there is a case of leading decrease in reliability with respect to appearance of chip cracks and the like.

A present fifteenth invention provides the semiconductor device as described in the tenth to thirteenth inventions, characterized in that the metal layer having a melting point of 260° C. or higher is made of at least one of Cu/Invar alloy/Cu composite material, Cu/Cu₂O composite material, Cu—Mo alloy, Ti, Mo, and W.

The Cu/Invar alloy/Cu composite material, Cu/Cu₂O composite material, Cu—Mo alloy, Ti, Mo, or W has a thermal expansion coefficient ranging from that of the semiconductor element to that of the Cu-based lead frame, whereby the thermal stress is buffered. In this case, a thickness thereof is preferably 30 μm or more. When the thickness is less than 30 μm, the thermal stress cannot be sufficiently buffered, so that there is a case where chip cracks appear.

A present sixteenth invention provides a manufacturing method for a semiconductor device wherein a semiconductor element is die-mount-connected onto a lead frame by means of a metal joint, wherein the metal joint is formed by heating a composite foil in a condition where the composite foil comprising a layer composing a metal having a melting point of 260° C. or lower and a metal having a melting point of 260° C. or higher that react to form an intermetallic compound having a melting point of 260° C. or less, the composite foil is disposed on the semiconductor element side and the lead frame side of a metal layer having a melting point of 260° C. or higher, the semiconductor element and the lead frame are interposing the composite foil between the metal layer.

A present seventeenth invention provides the manufacturing method for a semiconductor device as described in the sixteenth invention, characterized in that the metal layer having a melting point of 260° C. or higher is formed by any one of Al, Mg, Ag, Zn, Cu, and Ni; the metal having a melting point of 260° C. or lower and forming an intermetallic compound having a melting point of 260° C. or higher as a result of reaction is any one of Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, and Bi—In-based Pb-free solders; and the metal having a melting point of 260° C. or higher and forming an intermetallic compound having a melting point of 260° C. or higher as a result of reaction is any one metal of Cu, Ag, Ni, and Au.

According to the present invention, in the case of reflow soldering of a material onto a substrate at the highest temperature of 260° C., it is possible to provide a Pb-free power semiconductor device with accompanying no flash of the solder in a die-mount-connection part and also a high connection reliability in the die-mount-connection part of a power semiconductor element and a lead frame in the power semiconductor device under the actual use environment even in the case where a thermal expansion coefficient difference is large between the materials to be connected.

As described above, according to the present invention, it is possible to conduct a Pb-free die-mount connection without causing any chip crack with respect to thermal stress, and with no melting of the solder in the case of reflowing.

### BRIEF DESCRIPTIONS OF THE DRAWINGS

FIG. 1 is a sectional view schematically showing a configuration of a conventional power semiconductor device;

FIG. 2 is an explanatory view showing the appearance of flash due to a remelted solder;

FIG. 3 is a diagram showing Young's modulus and yield stresses of a variety of materials applicable for a stress buffering layer;

FIG. 4 is a sectional view schematically showing the power semiconductor device regarding to the present embodiment;

FIG. 5A is a sectional view schematically showing the constitution of a composite foil, and FIG. 5B is a sectional view schematically showing the appearance of a metal joint;

FIG. 6 is a perspective view schematically showing the composition of the power semiconductor device used in the experiment for determining a temperature and a retention time required for achieving a complete compound of a connection layer;

FIGS. 7A, 7B and 7C are sectional photographs each showing a connection section wherein Si is connected to Cu by the use of Sn-3Ag-0.5Cu at 350° C. in which the holding time is 1 minute, 5 minutes, and 10 minutes, respectively;

FIG. 8 is a sectional view schematically showing a modified example of the composite foil;

FIG. 9 is an example of a sectional photograph showing a situation of the connection part after applying the temperature cycles of Example 11;

FIG. 10 is an example of a sectional photograph showing a situation of the connection part after applying the temperature cycles of Example 14;

FIG. 11A is a sectional view schematically showing a modified example of the power semiconductor device according to the present embodiment; and FIG. 11B is a plan view showing a connecting condition of a power semiconductor element viewed from above;

FIG. 12 is an example of a sectional photograph showing appearance of a chip crack;

FIG. 13A is a sectional view schematically showing appearance of a modified example of the metal joint; and FIG. 13B is a sectional view schematically showing appearance and composition a modified example of the composite foil used for forming the metal joint shown in FIG. 13A;

FIGS. 14A through 14G are explanatory views each schematically illustrating a procedure in the case of manufacturing the semiconductor device die-mount-connected by means of the metal joint wherein the composite foil is used;

FIG. 15A is a sectional view schematically showing appearance of a modified example of the metal joint; and FIG. 15B is a sectional view schematically showing appearance and composition of a modified example of the composite foil used for forming the metal joint shown in FIG. 15A; and

FIG. 16A is a sectional view showing schematically the appearance of a modified example of a metal joint; and FIG. 16B is a sectional view schematically showing a modified example of the composite foil used for forming the metal joint shown in FIG. 16A.

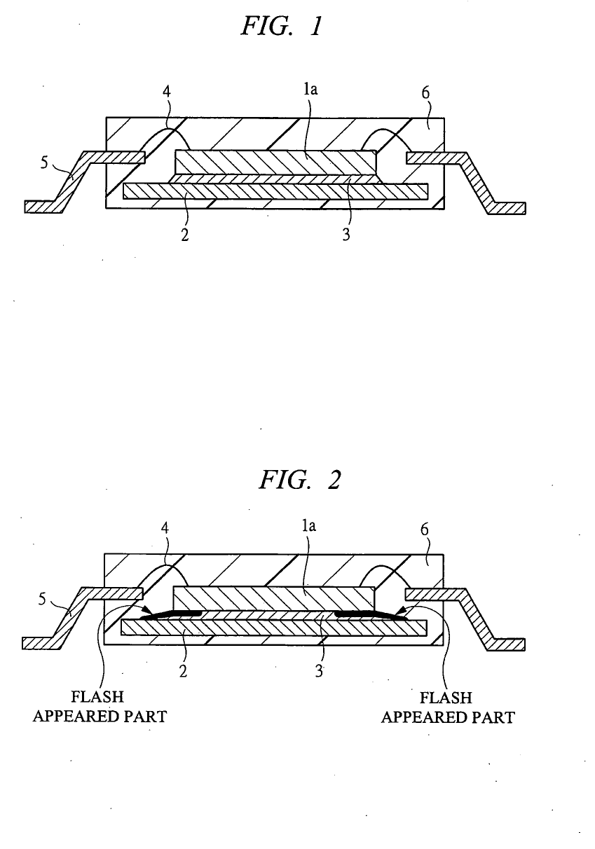

### BEST MODE FOR CARRYING OUT THE INVENTION

In the following, embodiments of the present invention will be described by referring to the accompanying drawings.

### Embodiment 1

FIG. 4 is a sectional view showing a semiconductor device 8 according to an embodiment of the present invention wherein the semiconductor device 8 comprising a power semiconductor device 8a and the like is manufactured in accordance with, for example, the following manufacturing processes.

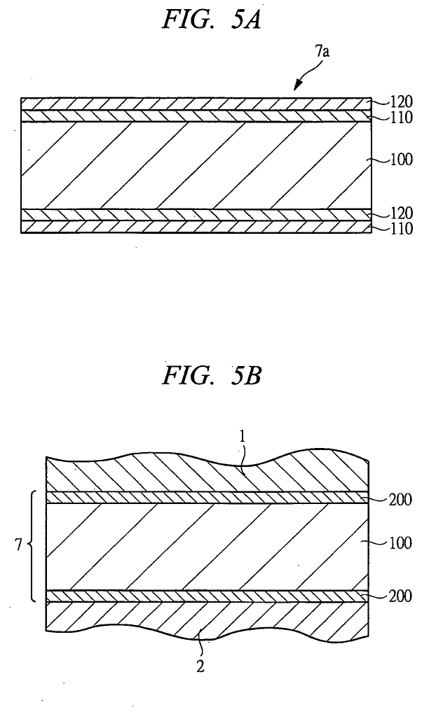

That is, as shown in FIG. 4, the power semiconductor device 8a is obtained by die-mount-connecting a semiconductor element 1 as a power semiconductor element 1a onto a lead frame 2 through a metal joint section 7. To form the metal joint section 7, a composite foil 7a for forming the joint section shown in FIG. 5A is disposed on a die pad of the lead frame 2, and further the power semiconductor device 8a is disposed on the composite foil 7a and heated.

For instance, on the rear surface on the silicon (Si) side of the power semiconductor element 1a being in contact with the composite foil 7a, Ti/Ni/Au is metallized to assure the wettability. The lead frame 2 is, for example, made of a copper(Cu)-based material having good coefficient of thermal conductivity. The power semiconductor element 1a and the lead frame 2 having such composition as described above are joined to the metal joint section 7 formed by such a manner that the composite foil 7a interposed between the power semiconductor element 1a and the lead frame 2 is heated at a predetermined temperature to melt and solidify at the time of die-mount-connecting.

The composite foil 7a for forming the metal joint section 7 is made of, for example, a metal layer 100 having a high melting point of 260° C. or higher sandwiched between other metal layers 110 each having a high melting point of 260° C. or higher, and further the other metal layers 120 laminated on the metal layers 110 having a low melting point of 260° C. or lower. In order to assure the wettability between the power semiconductor element 1a or the lead frame 2, the metal layer 120 of a low melting point metal is disposed on the metal layer 110 of a high melting point metal.

Examples of the metals to constitute the metal layer 100 include aluminum (Al), magnesium (Mg), silver (Ag), zinc (Zn), copper (Cu), nickel (Ni), and the like. Since such metal has a smaller yield stress than that of Au-20Sn as a hard solder, it is easily subjected to plastic deformation. Thus, when a thermal stress appears in the metal joint section 7, the metal layer 100 is subjected to plastic deformation, whereby the stress reaches to the side of the power semiconductor device 8a, so that the metal layer 100 brings out a function for buffering the thermal stress so as not to result in a damage such as occurrence of cracks.

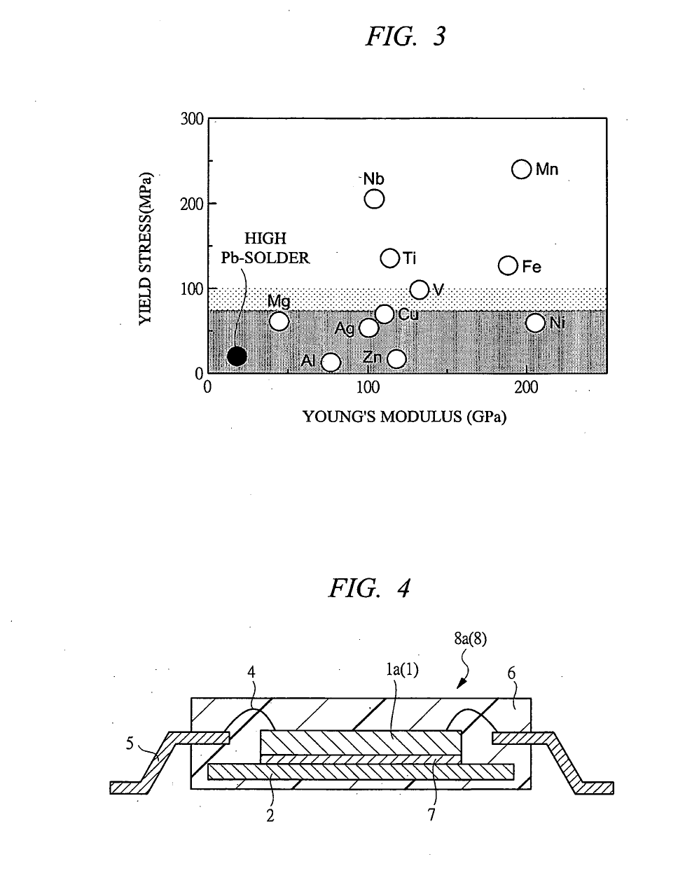

As shown in FIG. 3, from the present experimental results by the present inventors, it was found that, when the yield stress of the metal layer 100 is 100 MPa or more, the thermal stress cannot be sufficiently buffered, whereby the stress produced on the semiconductor element increases, so that there is a case where chip cracks occur. Accordingly, it is preferred that the yield stress is less than 100 MPa, and more preferably a magnitude of the yield stress is 75 MPa or less as shown in FIG. 3.

Concerning a stress buffering function of the metal layer 100, although it does not significantly depend on Young's modulus of a material constituting the metal layer 100, the smaller value is the more preferable.

A thickness of the metal layer 100 is preferably to be 30 to 200 μm. When the thickness is less than 30 μm, the thermal stress is not sufficiently buffered, so that there is a case where chip cracks appear. On the other hand, when the thickness is 200 μm or more, effects of thermal expansion coefficient increase because of Al, Mg, Ag, or Zn having a larger thermal expansion coefficient than that of the Cu frame. Hence, there is a case where it results in decrease in reliability due to the generation of chip cracks and the like.

On the other hand, examples of the high melting point metal to constitute the metal layer 110 include copper (Cu), silver (Ag), nickel (Ni), gold (Au) and the like. Furthermore, as a low melting point metal constituting the metal layer 120, any of Sn—Ag-based (tin-silver-based), Sn—Cu-based (tin-copper-based), Sn—Ag—Cu-based (tin-silver-copper-based), Sn—Zn-based (tin-zinc-based), Sn—Zn—Bi-based (tin-zinc-bismuth-based), Sn—In-based (tin-indium-based), In—Ag-based (indium-silver-based), In—Cu-based (indium-copper-based), Bi—Sn-based (bismuth-tin-based), and Bi—In (bismuth-indium-based) Pb-free solders is preferably applied.

The metal layers 110 may be provided on the metal layer 110 by means of, for example, sputtering or plating technique. Similarly, the metal layers 120 may be also provided on the metal layers 110, respectively, by means of, for example, sputtering or plating technique.

In the composite foil 7a having such configuration as described above, the high melting point metal constituting the metal layers 110 and the low melting point metal constituting the metal layers 120 are melted to react with each other as a result of heating at the time of die-mount-connection, whereby both connection layers 200 are formed on the metal layer 100 as shown in FIG. 5B.

The connection layer 200 is a product formed by the reaction of the high melting point metal of the metal layer 110 with the low melting point metal of the metal layer 120. Judging from the microgram of a section of the metal joint section 7, the product exhibits a condition wherein a plurality of phases of: an intermetallic compound of such a low melting point metal and a high melting point metal; another intermetallic compound of the low melting point metal, the high melting point metal, and a metal metallized on the rear surface of the semiconductor element 1; and a single phase metal and the like exist being mixed in the melted metal phase of a low melting point metal.

When the connection layer 200 formed by the reaction of a high melting point metal constituting the metal layer 110 with a low melting point metal constituting the metal layer 120 is held, for example, at 350° C. for 10 minutes after the die mounting, the connection layer 200 turns to have a high melting point as a result of achieving a complete compound through the reaction of a metal having a melting point of 260° C. or lower with another metal having a melting point of 260° C. or higher.

In the power semiconductor element 1a die-mount-connected by means of the metal joint section 7 which was modified to have a high melting point, the electrode formed on the top of the power semiconductor element 1a is then bonded to the leads 5 by using the Au wires 4, respectively. In addition, the power semiconductor element 1a, the lead frame 2, the metal joint section 7, and the wires 4 are sealed with the use of an epoxy-based resin 6. According to the above-described processes, the power semiconductor device 8a is manufactured.

Such a condition that the composite foil 7a sandwiched between the power semiconductor element 1a and the lead frame 2 is held at 350° C. for 10 minutes in the case of achieving a complete compound of the connection layer 200 formed by the reaction of the metal layer 110 with the metal layer 120 is determined by the experimental results wherein connection temperatures and holding times are applied as the parameters in a variety of connection structures shown in Table 1.

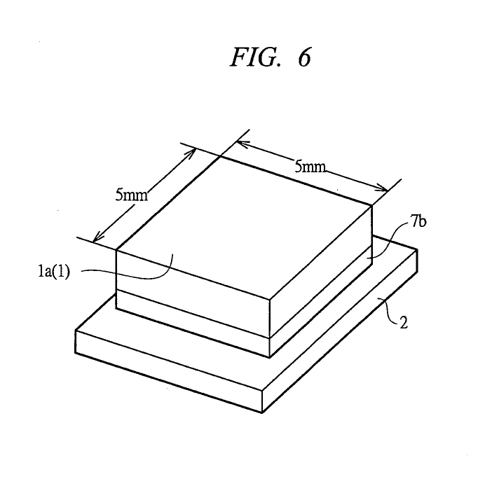

Namely, the experiments were conducted in such a manner that a composite foil 7b which becomes the connection layer 200 having a high melting point as a result of heating the composite foil 7b is interposed between the 5 mm square power semiconductor element 1a and the Cu lead frame 2 to which no mold was applied as shown schematically in FIG. 6.

An example of the composite foil 7b applied includes, as shown in Table 1, an Sn composite foil of 20 μm layer thickness, an Sn-3Ag-0.5Cu composite foil of 20 μm layer thickness, an Sn-9Zn composite foil of 20 μm, an In-48Sn composite foil of 20 μm layer thickness, and an Sn-0.7Cu composite foil of 20 μm layer thickness. Each of the composite foils 7b is interposed between the power semiconductor element 1a and the lead frame 2, and it is heated at each of temperatures of 300° C., 350° C., and 400° C. for each of holding times 1 minute, 3 minutes, 5 minutes, 10 minutes, 30 minutes, and 60 minutes, respectively. Then, each condition of the achievement of complete compounds was confirmed with respect of each of the connection layers 200 after the heating.

Note that, the composite foil 7b does not contain the constitution corresponding to the metal layer 100 exerting the above-mentioned stress buffering functions, because the experiments are conducted for the purposes of determining the heating temperatures and the heating holding time required for achieving the complete compounds forming the connection layer 200.

TABLE 1

| | Connection | Holding Time | | | | | |
|---|---|---|---|---|---|---|---|
| Connection Structure | Temperature | 1 min. | 3 min. | 5 min. | 10 min. | 30 min. | 60 min. |
| Si/Sn(20 μm)/Cu | 300° C. | X | X | X | X | 603 | 603 |
| | 350° C. | X | X | X | 603 | 603 | 603 |
| | 400° C. | X | X | X | 603 | 603 | 603 |
| Si/Sn—3Ag—0.5Cu(20 μm)/Cu | 300° C. | X | X | X | X | 603 | 603 |
| | 350° C. | X | X | X | 603 | 603 | 603 |
| | 400° C. | X | X | X | 603 | 603 | 603 |
| Si/Sn—9Zn(20 μm)/Cu | 300° C. | X | X | X | 603 | 603 | 603 |
| | 350° C. | X | X | X | 603 | 603 | 603 |
| | 400° C. | X | X | X | 603 | 603 | 603 |
| Si/In—48Sn(20 mm)/Cu | 300° C. | X | X | X | 603 | 603 | 603 |
| | 350° C. | X | X | X | 603 | 603 | 603 |
| | 400° C. | X | X | X | 603 | 603 | 603 |
| Si/Sn—0.7Cu(20 mm)/Cu | 300° C. | X | X | X | 603 | 603 | 603 |
| | 350° C. | X | X | X | 603 | 603 | 603 |
| | 400° C. | X | X | X | 603 | 603 | 603 |

Table 1 was obtained by sorting out the results with respect to the achievement of the complete compounds of the connection parts of the samples to which Si/solder/Cu connection was applied. As shown in Table 1, it was found that the complete compounds of the connection layers 200 can be achieved in the case where the heating temperature is 350° C. or higher and the holding time is 10 minutes or more as a result of the experiments wherein the composite foils 7b having the above-described five types of constitutions are applied.

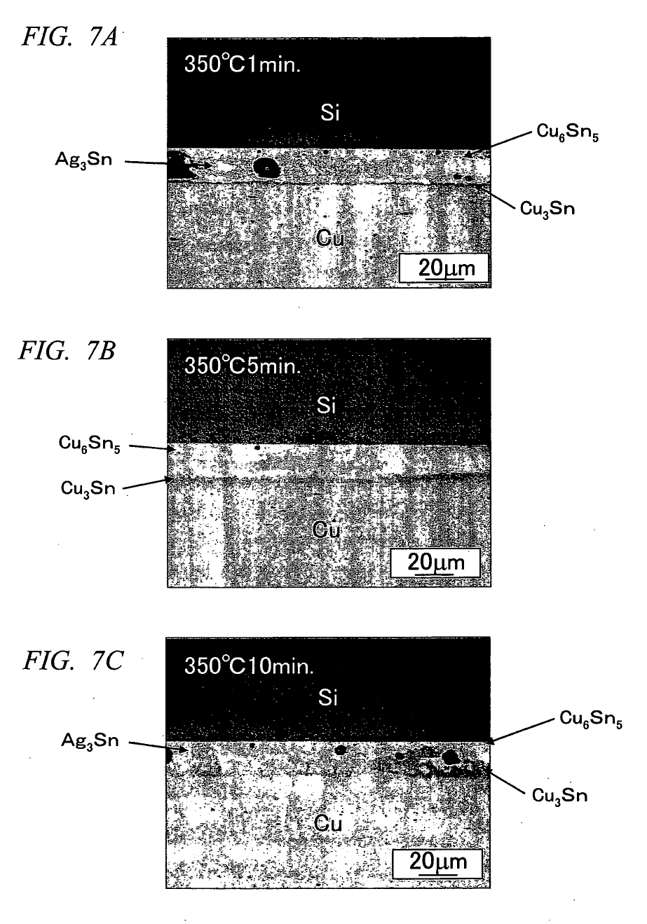

Incidentally, FIGS. 7A to 7C indicate each of conditions of the connection sections wherein a semiconductor element (Si) is connected with Cu at 350° C. by using Sn-3Ag-0.5Cu solder. FIGS. 7A and 7B are photographs of sectional views in the case where the holding time is 1 minute and 5 minutes, respectively, wherein it is found that Sn having a melting point of 260° C. or lower remains. In the case where the Sn, which does not reach the complete compound remains, remelting of a solder constituting the connection layer 200 arises at the time of reflow soldering. On the other hand, it is confirmed as shown in FIG. 7C that when the holding time is 10 minutes, the connection layer 200 is completely turned into a whole compound with Cu—Sn and an Ag—Sn compound.

Next, effectiveness of the present invention was verified in the case where the power semiconductor element 1a was die-mount-connected by using the composite foil 7a to which the metal layer 100 exerting stress buffering functions as shown in FIG. 5A was applied, and the thermal stress due to temperature cycles was applied repeatedly.

More specifically, the experiments were conducted in such a manner that the composite foil 7a obtained by laminating the metal layers 110 and 120 on the metal layer 100 which becomes the connection layer 200 having a high melting point as a result of heating them is interposed between the 5 mm square power semiconductor element 1a and the Cu lead frame 2 to which no mold has been applied.

The composite foil 7a to be used is prepared in example 1, as shown in table 2, in such that the metal layer 100 is made of an Al layer having a layer thickness of 100 μm, the metal layer 110 is made of Cu, the metal layer 120 is made of Sn, and a layer thickness of a combination of those of the metal layers 110 and 120 is made to be 10 μm.

A layer thickness of the metal layers 110 and 120 may be determined, for example, to be the layer thickness corresponding to such an amount wherein a metal of a low melting point does not remain in the form of the single phase thereof in the case where a metal having a high melting point constituting the metal layer 110 reacts with the metal having a low melting point constituting the metal layer 120 to form an intermetallic compound as described later. This is because the metal of a low melting point remelts at the temperature of 260° C. in the case of reflow in a condition wherein a metallic phase of the low melting point remains, whereby there is a fear of a cause for occurring flash.

A semiconductor package is formed by using the power semiconductor device 8a having the constitution shown in FIG. 4 which is obtained as a result of the die-mount-connection wherein the composite foil 7a having the above-described constitution is interposed between the power semiconductor element 1a and the Cu-based lead frame 2, and they are maintained at a heating temperature of 350° C. for a holding time of 10 minutes while keeping the interposed condition.

With respect to twenty power semiconductor packages each having the above-described constitution, a temperature cycle test for 500 cycles of −55° C.(30 min.)/150° C.(30 min.) was implemented. The temperature cycle test was conducted by setting the semiconductor package in a thermal-shock tester. When the connection section after the temperature cycle test is observed, in the case where the metal layer 100 of Al in example 1 functions to buffer thermal stress, cracks appear in an area ratio of Al of less than 5% wherein the area extending from the end of Al to the connection section, while no chip crack appears in the side of the power semiconductor element 1a.

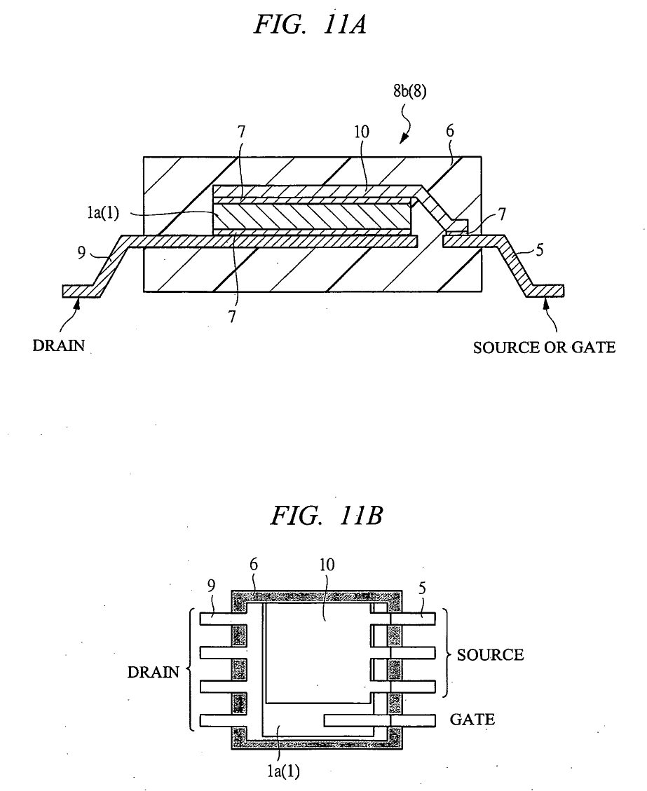

TABLE 2

| | | Package | | | Chip |
|---|---|---|---|---|---|
| No. | | Structure | Frame | Configuration of Die-Mount-Connection | Crack |
| Example | 1 | FIG. 4 | Cu-Based | Cu + Sn/Al/Cu + Sn = 10 μm/100 μm/10 μm | 0/20 |
| | 2 | FIG. 4 | Cu-Based | Cu + Sn—3Ag—0.5Cu/Al/Cu + Sn—3Ag—0.5Cu = 10 μm/100 μm/10 μm | 0/20 |
| | 3 | FIG. 4 | Cu-Based | Cu + Sn—9Zn/Al/Cu + Sn—9Zn = 10 μm/100 μm/10 μm | 0/20 |
| | 4 | FIG. 4 | Cu-Based | Au + Sn/Al/Au + Sn = 10 μm/100 μm/10 μm | 0/20 |
| | 5 | FIG. 4 | Cu-Based | Ni + Sn/Al/Ni + Sn = 10 μm/100 μm/10 μm | 0/20 |
| | 6 | FIG. 4 | Cu-Based | Ag + Sn/Al/Ag + Sn = 10 μm/100 μm/10 μm | 0/20 |
| | 7 | FIG. 4 | Cu-Based | Cu + In—48Sn/Al/Cu + In—48Sn = 10 mμm/100 μm/10 μm | 0/20 |
| | 8 | FIG. 4 | Cu-Based | Ag + Bi—43Sn/Al/Ag + Bi—43Sn = 10 mμm/100 μm/10 μm | 0/20 |
| | 9 | FIG. 4 | Cu-Based | Cu + Sn/Zn/Cu + Sn = 10 μm/100 μm/10 μm | 0/20 |
| | 10 | FIG. 4 | Cu-Based | Sn/(Cu/Inver/Cu)/Sn = 10 μm/100 μm/10 μm | 0/20 |
| | 11 | FIG. 4 | Cu-Based | Au—20Sn/Al/Au—20Sn = 20 μm/100 μm/20 μm | 0/20 |
| | 12 | FIG. 4 | Cu-Based | Au—20Sn/Zn/Au—20Sn = 20 μm/100 μm/20 μm | 0/20 |
| | 13 | FIG. 4 | Cu-Based | Zn—6Al/Al/Zn—6Al = 20 μm/100 μm/20 μm | 0/20 |
| | 14 | FIG. 4 | Cu-Based | Au—20Sn/(Cu/Inver/Cu)/Au—20Sn = 20 μm/100 μm/20 μm | 0/20 |
| | 15 | FIG. 4 | Cu-Based | Au—20Sn/Ti/Au—20Sn = 20 μm/100 μm/20 μm | 0/20 |
| | 16 | FIG. 4 | Cu-Based | Bi—Ag/Al/Bi—Ag = 20 μm/100 μm/20 μm | 0/20 |
| | 17 | FIG. 4 | Cu-Based | Bi/(Cu/Inver/Cu)/Bi = 20 μm/100 μm/20 μm | 0/20 |
| | 18 | FIG. 11 | Cu-Based | Cu + Sn/Al/Cu + Sn = 10 μm/100 μm/10 μm | 0/20 |
| | 19 | FIG. 4 | 42-Alloy | Cu + Sn/Al/Cu + Sn = 10 μm/100 μm/10 μm | 0/20 |
| | 20 | FIG. 4 | Cu-Based | Au—20Sn/Al/Bi = 20 μm/100 μm/20 μm | 0/20 |
| | 21 | FIG. 4 | Cu-Based | Au—20Sn/(Cu/Inver/Cu)/Bi = 20 μm/100 μm/20 μm | 0/20 |
| | 22 | FIG. 4 | Cu-Based | Au—20Sn/Al/Bi—3Ag = 20 μm/100 μm/20 μm | 0/20 |
| | 23 | FIG. 4 | Cu-Based | Zn—9Al/Al/Au—20Sn = 20 μm/100 μm/20 μm | 0/20 |
| | 24 | FIG. 4 | Cu-Based | Au—20Sn/(Cu/Inver/Cu)/Sn = 10 μm/100 μm/10 μm | 0/20 |
| | 25 | FIG. 4 | Cu-Based | Bi/(Cu/Inver/Cu)/Sn = 10 μm/100 μm/10 μm | 0/20 |
| | 26 | FIG. 4 | Cu-Based | Cu + Sn/Al/Cu + In—48Sn = 10 μm/100 μm/10 μm | 0/20 |
| | 27 | FIG. 4 | Cu-Based | Ag + Sn/Al/Ag + Sn—9Zn = 20 μm/100 μm/20 μm | 0/20 |
| | 28 | FIG. 4 | Cu-Based | Sn/(Cu/Inver/Cu)/In—48Sn = 10 μm/100 μm/10 μm | 0/20 |
| | 29 | FIG. 4 | Cu-Based | Sn—3.5Ag/(Cu/Inver/Cu)/In—48Sn = 10 μm/100 μm/10 μm | 0/20 |
| | 30 | FIG. 4 | Cu-Based | Sn/(Cu/Inver/Cu)/Sn—9Zn = 10 μm/100 μm/10 μm | 0/20 |
| | 31 | FIG. 4 | Cu-Based | Cu + Au—20Sn/Al/Cu + Sn = 20 μm/100 μm/20 μm | 0/20 |
| | 32 | FIG. 4 | Cu-Based | Cu + Bi/Al/Cu + Sn = 10 μm/100 μm/10 μm | 0/20 |
| Comparative | 1 | FIG. 4 | Cu-Based | Pb—5Sn = 20 μm | 0/20 |
| Example | | | | | |
| | 2 | FIG. 4 | Cu-Based | Cu + Sn = 20 μm | 6/20 |
| | 3 | FIG. 4 | Cu-Based | Au—20Sn = 20 μm | 5/20 |

Temperature Cycle Test: 500 Cycles. Si/Composite Foil/Cu. 5 mm□. No Mold

Table 2 is obtained by sorting out results of the temperature cycle test wherein the samples prepared as a result of die-mount-connection by the use of the composite foil 7a applied in the present invention together with the results of comparative examples. As shown in Table 2, no chip crack appeared in all the twenty samples; and further no appearance of crack and the like were observed on the side of the power semiconductor element 1a in spite of the fact that repeated thermal stress due to the temperature cycles was applied. Namely, it has been verified that the connection reliability of the die-mount-connection by the use of the composite foil 7a according to the present invention is effective in example 1.

It is supposed that such effectiveness is due to the fact that the thermal stress derived from temperature cycle is buffered by the metal layer 100 of Al, so that such adverse effects of cracks on the side of the power semiconductor element 1a due to the thermal stress did not appear. More specifically, the stress as to extraction and contraction of the Cu lead frame is absorbed by the metal layer 100 on which the connection layer 200 is laminated in such large extraction and contraction in the Cu lead frame 2 having a large thermal expansion coefficient as to thermal stress.

Thus, the shear stress based on expansion and contraction on the side of the Cu lead frame 2 is absorbed as a result of the appearance of cracks in the metal layer 100, so that such a degree of the stress due to which chip cracks appear on the power semiconductor element 1a through the connection layer 200 laminated on the metal layer 100 is not transmitted to the side of the power semiconductor element 1a.

The same tendency could have been confirmed also in examples 2 through 10 indicated in Table 2 wherein the same temperature cycle test is conducted. In example 2, the composite foil 7a applied is made of, as indicated in Table 2, the metal layer 100 made of an Al layer having 100 μm layer thickness, the metal layer 110 made of Cu, and the metal layer 120 made of a Pb-free solder of Sn-3Ag-0.5Cu wherein the total layer thickness of the metal layers 110 and 120 is made to be 10 μm. In this case, although cracks appeared in an area ratio of Al constituting the metal layer 100 of less than 5% wherein the area extending from the end of Al to the connection section, no chip crack appeared in all the twenty samples.

In example 3, the composite foil 7a applied is made of, as indicated in Table 2, the metal layer 100 made of an Al layer having 100 μm layer thickness, the metal layer 110 made of Cu, and the metal layer 120 made of a Pb-free solder of Sn-9Zn wherein the total layer thickness of the metal layers 110 and 120 is made to be 10 μm. In example 3 also, although cracks appeared in an area ratio of Al within a range of less than 5%, no chip crack appeared in all the twenty samples as in the case of the above-described example 1.

In example 4, the composite foil 7a applied is made of, as indicated in Table 2, the metal layer 100 made of an Al layer having 100 μm layer thickness, the metal layer 110 made of Au, and the metal layer 120 made of Sn wherein the total layer thickness of the metal layer 110 and 120 is made to be 10 μm. In example 4 having the above-described constitution also, although cracks appeared in an area ratio of Al within a range of less than 5%, no chip crack appeared in all the twenty samples as in the case of the above-described example 1.

In example 5, the composite foil 7a applied is made of, as indicated in Table 2, the metal layer 100 made of an Al layer having 100 μm layer thickness, the metal layer 110 made of Ni, and the metal layer 120 made of Sn wherein the total layer thickness of the metal layer 110 and 120 is made to be 10 μm. In example 6, the composite foil 7a applied is made of, as indicated in Table 2, the metal layer 100 made of an Al layer having 100 μm layer thickness, the metal layer 110 made of Ag, and the metal layer 120 made of Sn wherein the total layer thickness of the metal layers 110 and 120 is made to be 10 cm.

In example 7, the composite foil 7a applied is made of, as indicated in Table 2, the metal layer 100 made of an Al layer having 100 μm layer thickness, the metal layer 110 made of Cu, and the metal layer 120 made of In-48Sn wherein the total layer thickness of the metal layers 110 and 120 is made to be 10 μm. In example 8, the composite foil 7a applied is made of, as indicated in Table 2, the metal layer 100 made of an Al layer having 100 μm layer thickness, the metal layer 110 made of Ag, and the metal layer 120 made of Bi-43Sn wherein the total layer thickness of the metal layers 110 and 120 is made to be 10 μm.

In examples 5 to 8 having also the above-described constitutions, respectively, although cracks appeared in an area ratio of Al within a range of less than 5%, no chip crack appeared in all the twenty samples as in the case of the above-described example 1.

In example 9, the composite foil 7a applied is made of, as indicated in Table 2, the metal layer 100 made of an Zn layer having 100 μm layer thickness, the metal layer 110 made of Cu, and the metal layer 120 made of Sn wherein the total layer thickness of the metal layers 110 and 120 is made to be 10 μm. In example 10, the composite foil 7a applied is made of, as indicated in Table 2, the metal layer 100 made of a Cu/Invar alloy/Cu layer having 100 μm layer thickness, the metal layer 110 using commonly the Cu with that of the metal layer 100, and the metal layer 120 made of Sn wherein the layer thickness of the metal layer 120 of Sn is made to be 10 μm.

In the case of example 9, although cracks appeared in an area ratio of Zn constituting the metal layer 100 of less than 5% wherein the area extending from the end of Zn to the connection section, no chip crack appeared in all the twenty samples. The case of example 10 is the one wherein the metal layer 100 is the Cu/Invar alloy/Cu having the intermediate thermal expansion coefficient in between Si and Cu; and when the connection section thereof is observed, there was no appearance of cracks in any of the Si, the intermetallic compound, and the Cu/Invar alloy/Cu.

From the results of examples 1 through 10, it has been found that, the constitutions of the present invention, thermal stress due to the temperature cycles can be buffered by the metal layer 100 accompanied by Al, Zn, or the Cu/Invar alloy/Cu and further there is no appearance of drawbacks such as chip cracks, so that the constitutions of the invention exhibit sufficient connection reliability.

According to the experiments by the present inventors, it has been confirmed that the formation of an intermetallic compound in the connection layer 200 arises in the interface between a melted metal of a low melting point and another metal of a high melting point. Such a condition wherein the formed compound falls off from the interface into the melted metal in the form of, for example, floating islands was observed. It seems that layers of compounds and the like having plural compositions are mixed in a metal of a low melting point to form inhomogeneous textures.

For instance, in the experiments of actual condition, it has been confirmed that Cu—Sn compounds (Cu₆Sn₅, Cu₃Sn), Cu—Ni—Sn compounds are formed on the chip side, while Cu—Sn compounds (Cu₆Sn₅, Cu₃Sn) are formed on the Cu frame side in the case where Sn is used as the metal of a low melting point, and Cu is used as the metal of a high melting point in examples 1, 9, and 10.

As the phases formed in example 2 (Cu+Sn-3Ag-0.5Cu), it has been confirmed that phases of Cu—Sn compounds (Cu₆Sn₅, Cu₃Sn), Ag—Sn compounds (Ag₃Sn), and Cu—Ni—Sn compounds are present on the chip side, while phases of Cu—Sn compounds (Cu₆Sn₅, Cu₃Sn), and Ag—Sn compounds (Ag₃Sn) are present on the Cu frame side.

As the phases formed in example 3 (Cu+Sn-9Zn), it has been confirmed that phases of Cu—Sn compounds (Cu₆Sn₅, Cu₃Sn), and Cu—Zn compounds are present on the chip side, while phases of Cu—Zn compounds, and Cu—Sn compounds (Cu₆Sn₅, Cu₃Sn) are present on the Cu frame side.

As the phases formed in example 4 (Au+Sn), it has been confirmed that phases of Au—Sn compounds are present on the chip side, while phases of Au—Sn compounds, and Cu—Sn compounds (Cu₆Sn₅, Cu₃Sn) are present on the Cu frame side.

As the phases formed in example 5 (Ni+Sn), it has been confirmed that phases of Ni—Sn compounds are present on the chip side, while phases of Ni—Sn compounds, Cu—Sn compounds (Cu₆Sn₅, Cu₃Sn), and Ni—Cu—Sn compounds are present on the Cu frame side.

As the phases formed in example 6 (Ag+Sn), it has been confirmed those phases of Ag—Sn compounds (Ag₃Sn), and Ag-rich hcp phases are present on the chip side, while phases of Ag—Sn compounds (Ag₃Sn), Ag-rich hcp phases, and Cu—Sn compounds (Cu₆Sn₅, Cu₃Sn) phases are present on the Cu frame side.

As the phases formed in example 7 (Cu+In-48Sn), it has been confirmed that phases of Cu—Sn compounds (Cu₆Sn₅, Cu₃Sn), In—Cu compounds, and In—Sn—Cu compounds are present on the chip side, while phases of Cu—Sn compounds (Cu₆Sn₅, Cu₃Sn), In—Cu compounds, and In—Sn—Cu compounds are present on the Cu frame side.

As the phases formed in example 8 (Ag+Bi-43Sn), it has been confirmed that phases of Ag—Sn compounds (Ag₃Sn), Ag-rich hcp phases and, Bi phases are present on the chip side, while phases of Ag—Sn compounds (Ag₃Sn), Ag-rich hcp phases, Bi, and Cu—Sn compound (Cu₆Sn₅, Cu₃Sn) phases are present on the Cu frame side.

### Embodiment 2

As is apparent from the above-described embodiment 1, such a construction which is not adversely affected, e.g. with appearance of cracks, by the rigid and brittle connection layer 200 and the side of the power semiconductor element 1a connected with the connection layer 200 may be obtained by the provision of the metal layer 100 wherein thermal stress is absorbed by the metal layer 100, even if the connection layer 200 comes to have a high melting point resulting in rigid and brittle characteristics.

In this connection, the present inventors get such an idea that when a Pb-free solder of a high melting point is used together with the metal layer 100, it becomes possible to use the Pb-free solder which could not have been used for the die-mount-connection because of occurrence of cracks by thermal stress on the chip side due to the rigid and brittle characteristics thereof although there is no fear of the remelting in the case of the reflow by making it to have a high melting point.

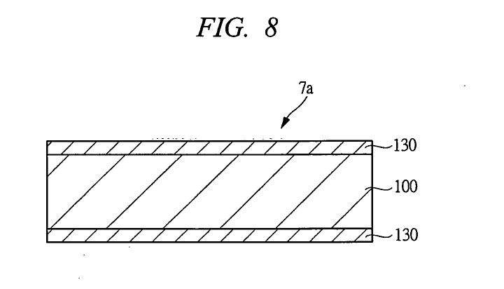

More specifically, in the present embodiment, such a constitution wherein Pb-free solder layers being metal layers 130 with which a high melting point may be achieved are provided on the opposite surfaces of a metal layer 100 as a composite foil 7a is adopted as shown in FIG. 8.

The constitution of the power semiconductor device 8a used in the present embodiment is the same as that of the embodiment 1 shown in FIG. 4. However, the constitution of the composite foil 7a which is used for forming a metal joint section 7 in the case of die-mount-connecting a power semiconductor element 1a with a lead frame 2 is not the one shown in FIG. 5A, but the one shown in FIG. 8 so that the present embodiment differs from the embodiment 1 in this respect.

In the present embodiment, the respective composite foils 7a have the constitutions of examples 11 through 15 as shown in Table 2. In cases of examples 11 through 15, each of 5 mm square power semiconductor elements 1a to which no mold has been applied are used as in the cases of examples 1 through 10.

Namely, in example 11, the composite foil 7a applied is made of the metal layer 100 made from an Al layer having 100 μm layer thickness, and the metal layer 130 made from an Au-20Sn layer being a high melting point Pb-free solder having 20 μm layer thickness as shown in Table 2. In example 12, the composite foil 7a applied is made of the metal layer 100 made from a Zn layer having 100 μm layer thickness, and the metal layer 130 made from the Au-20Sn layer being the high melting point Pb-free solder having 20 μm layer thickness as shown in Table 2.

In example 13, the composite foil 7a applied is made of the metal layer 100 made from an Al layer having 100 μm layer thickness, and the metal layer 130 made from a Zn-6Al layer being a high melting point Pb-free solder having 20 μm layer thickness as shown in Table 2. In example 14, the composite foil 7a applied is made of the metal layer 100 made from a Cu/Invar alloy/Cu layer having 100 μm layer thickness, and the metal layer 130 made from the Au-20Sn layer being the high melting point Pb-free solder having 20 μm layer thickness as shown in Table 2. In example 15, the composite foil 7a applied is made of the metal layer 100 made from a Ti layer having 100 μm layer thickness, and the metal layer 130 made from the Au-20Sn layer being the high melting point Pb-free solder having 20 μm layer thickness as shown in Table 2.

With respect to the power semiconductor packages of examples 11 through 15 wherein each of the composite foils 7a having the above-described constitutions, 500 cycles each of temperature cycle tests of −55° C.(30 min.)/150° C.(30 min.) are applied to twenty packages of each example as in the case of the above-described embodiment 1. As a result, no chip crack did appear in all the examples 11 through 15 as indicated in Table 2.

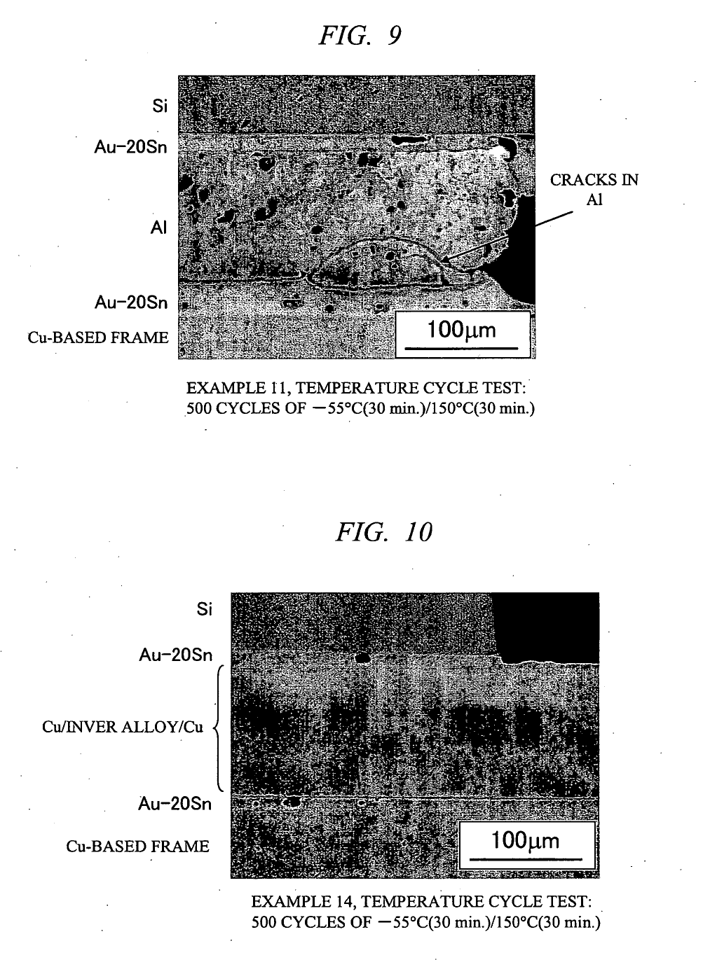

On the other hand, when the connection section is observed, cracks appear in an area of Al of less than 5% wherein the area extending from the end of Al to the connection section in the case where the metal layer 100 of Al in examples 11 and 13 functions to buffer thermal stress. FIG. 9 is a photograph, in section, showing the condition of cracks in Al appeared in the case of example 11.

In the case of example 12 wherein the metal layer 100 is Zn, cracks appear in an area of Zn of less than 5% wherein the area extending from the end of Zn to the connection section. In the case of examples 14 and 15 wherein the metal layer 100 is Cu/Invar alloy/Cu, and Ti having an intermediate thermal expansion coefficient in between Si and Cu, no crack appears in any of Si, the solder, the Cu/Invar alloy/Cu, and Ti. FIG. 10 is a photograph, in section, showing the connection section in the case of example 14. From the photograph, it is confirmed that there is no crack in the metal layers 100 and 130 as well as on the Si side of the power semiconductor element 1a.

From the fact as mentioned above in the present embodiment, it has been found that thermal stress due to the temperature cycles are buffered by means of the metal layer 100 of Al, Zn, the Cu/Invar alloy/Cu, and Ti to results in no appearance of chip crack, so that sufficient connection reliability can be obtained according to the present embodiment.

From the above results, it has been confirmed that when a stress buffering layer is provided, a high-melting point Pb-free solder such as Au-20Sn which could not have been sufficiently used heretofore because of such reason that it can make to have a high melting point, but it turns into rigid and brittle on the other hand may be applied for die-mount-connection. In addition, when the stress buffering layer is provided, the Pb-free solder layer which contributes actually for the connection may be made thinner, whereby the Au-20Sn can be inexpensively applied.

### Embodiment 3

As is apparent from the above embodiment 1, such a construction which is not adversely affected, e.g. with appearance of cracks, by the rigid and brittle connection layer 200 and the side of the power semiconductor element 1a connected with the connection layer 200, may be obtained by the provision of the metal layer 100 wherein thermal stress is absorbed by the metal layer 100, even if the connection layer 200 comes to have a high melting point resulting in rigid and brittle characteristics.

In this connection, the present inventors get such an idea that when a Bi, a Bi—Ag alloy, a Bi—Cu alloy, or a Bi—Ag—Cu alloy-based solder is used together with the metal layer 100, it becomes possible to use any of these solders which could not have been used for the die-mount-connection because of occurrence of cracks by applying it thinly in spite of requiring the thin connection thereof due to its low thermal expansion coefficient of about 9 W/m·K, although there is no fear of the remelting in the case of the reflow by making it to have a high melting point.

More specifically, in the present embodiment, such a constitution wherein Pb-free solder layers 130 with which a high melting point may be achieved are provided on the opposite surfaces of a metal layer 100 as a composite foil 7a is adopted as shown in FIG. 8.

The constitution of the power semiconductor device 8a used in the present embodiment is the same as that of the embodiment 1 shown in FIG. 4. However, the constitution of the composite foil 7a which is used for forming a metal joint section 7 in the case of die-mount-connecting a power semiconductor element 1a with a lead frame 2 is not the one shown in FIG. 5A, but the one shown in FIG. 8 so that the present embodiment differs from the embodiment 1 in this respect.

In the present embodiment, the respective composite foils 7a have the constitutions of examples 16 and 17 as shown in Table 2. In cases of examples 16 and 17, each of 5 mm square power semiconductor elements 1a to which no mold has been applied are used as in the cases of examples 1 through 10.

Namely, in example 16, the composite foil 7a applied is made of the metal layer 100 made from an Al layer having 100 μm layer thickness, and the metal layer 130 made from an Bi—Ag layer being a high melting point Pb-free solder having 20 μm layer thickness as shown in Table 2. In example 17, the composite foil 7a applied is made of the metal layer 100 made from a Cu/Invar alloy/Cu layer having 100 μm layer thickness, and the metal layer 130 made from the Bi layer being the high melting point Pb-free solder having 20 μm layer thickness as shown in Table 2.

From the above results, it has been confirmed that when a stress buffering layer is provided, the Bi-, the Bi—Ag alloy-, the Bi—Cu alloy-, or the Bi—Ag—Cu alloy-based high-melting point Pb-free solders which could not have been sufficiently used heretofore because of the low coefficients of thermal expansion may be applied for die-mount-connection.

### Embodiment 4

In the present embodiment, the constitution of a composite foil 7a used for a metal joint section 7 of die-mount-connection with respect to a lead frame 2 of a power semiconductor element 1a adopts the same constitution as that of the above-described embodiment 1, but a power semiconductor device 8b (8) is constituted in a structure wherein a strap is used as shown in FIGS. 11A and 11B.

Namely, the power semiconductor device 8b is manufactured in accordance with the manufacturing process as described hereunder. The power semiconductor element 1a wherein the rear surface metallization is Ti/Ni/Au is die-mount-connected by the use of the composite foil 7a onto a Cu-based drain 9. Then, an electrode formed on the upper surface of the semiconductor element 1a is connected with a lead 5 functioning as the source and the gate by using the composite foil 7a and the Cu strap 10. After connecting the strap, they are maintained at 350° C. for 10 minutes, whereby the solder of the metal layer 120 of 260° C. or lower melting point is allowed to react with the metal of the metal layer 110 of 260° C. or higher melting point which constitute the composite foil 7a as shown in FIG. 5A to produce the complete compound, so that a connection layer 200 is made to have a high melting point.

Thus, in the power semiconductor device 8b, the power semiconductor element 1a is connected with the drain 9 and the strap 10 by metal joint sections 7 as well as the strap 10 is connected with the lead 5 by the metal joint section 7, respectively, as shown in FIG. 11A.

The composite foil 7a to be used is prepared in such that the metal layer 100 is made of an Al layer having a layer thickness of 100 μm, the metal layer 110 is made of Cu, the metal layer 120 is made of Sn, and a layer thickness of a combination of those of the metal layers 110 and 120 is made to be 10 μm as in example 18 shown in table 2. Then, the power semiconductor element 1a, the Cu strap 10, and the metal joint section 7 are sealed with the use of an epoxy-based resin 6 to fabricate the power semiconductor device 8b.

With respect to twenty power semiconductor packages wherein each of them uses the power semiconductor device 8b having the above-described constitution, a temperature cycle test for 500 cycles of −55° C.(30 min.)/150° C.(30 min.) was implemented as in the case of the above-described embodiment 1. As a result, no chip crack appeared in example 18 as indicated in Table 2. When the connection section is observed, cracks did appear in an area of Al, functioning to buffer thermal stress, of less than 5% wherein the area extending from the end of Al to the connection section.

From the fact as mentioned above, it has been found that thermal stress due to the temperature cycles are buffered by means of the metal layer 100 of Al in also the constitution of the power semiconductor device 8b having the structure wherein the strap is used as shown in FIG. 11, so that sufficient connection reliability can be obtained according to the present embodiment.

### Embodiment 5

Although the case where a Cu-based material having a large thermal expansion coefficient difference from that of Si in a semiconductor element 1 is used as a lead frame 2 has been described in the above-described embodiments 1 and 2, such verification is conducted in the present embodiment that an application of the present invention is possible with respect to a Fe-42Ni material as an iron (Fe group) alloy having a small thermal expansion coefficient difference, on the contrary.

Namely, a power semiconductor device 8a was fabricated by employing a 42-alloy frame in accordance with the same manner as that mentioned in the above-described embodiment 1. More specifically, it corresponds to the one wherein the lead frame 2 in the power semiconductor device 8a having the constitution shown in FIG. 4 is made from the 42-alloy, and the other parts of the constitution are the same as that of example 1 in the above-described embodiment 1.

The composite foil 7a to be used is prepared as in the case of example 1 in such that the metal layer 100 is made of an Al layer having a layer thickness of 100 μm, the metal layer 110 is made of Cu, the metal layer 120 is made of Sn, and a layer thickness of a combination of those of the metal layers 110 and 120 is made to be 10 μm as in example 19 shown in table 2.

A semiconductor package is formed by using the power semiconductor device 8a having the constitution shown in FIG. 4 which is obtained as a result of the die-mount-connection wherein the composite foil 7a having the above-described constitution is interposed between the power semiconductor element 1a and the lead frame 2 made of the 42-alloy, and they are maintained at a heating temperature of 350° C. for a holding time of 10 minutes while keeping the interposed condition.

With respect to twenty power semiconductor packages each being obtained by the use of the power semiconductor element 8a having the above-described constitution, a temperature cycle test for 500 cycles of −55° C.(30 min.)/150° C.(30 min.) was implemented as in the case of the above-described embodiment 1. As a result, no crack appeared in the chip and the connection part in example 19 as indicated in Table 2.

Moreover, although there is no indication in Table 2, the composite foils 7a having the same constitutions as that of examples 2 through 10 were used to fabricate the power semiconductor devices 8a. The temperature cycle test was conducted with respect to twenty semiconductor packages wherein the power semiconductor devices 8a as described above were used. As a result, no chip crack was observed with respect to all the packages.

From the fact as described above, it has been found that the present invention exhibits sufficient connection reliability with respect to not only a Cu-based frame having a large thermal expansion coefficient difference from that of Si, but also a lead frame having a small thermal expansion coefficient difference from that of Si.

### COMPARATIVE EXAMPLE 1

In the comparative example 1, unlike the present invention, a power semiconductor device 8a having the constitution as shown in FIG. 4 was fabricated by the use of a Pb-5Sn solder having 20 μm layer thickness without employing a composite foil 7a containing a metal layer 100 exerting stress buffering function.

With respect to twenty power semiconductor packages each being obtained by the use of the power semiconductor element 8a having the above-described constitution, a temperature cycle test for 500 cycles of −55° C.(30 min.)/150° C.(30 min.) was implemented in accordance with the same manner as that of examples 11 through 15.

As indicated in Table 2, no chip crack appeared in comparative example 1. However, when the connection section is observed, cracks appeared in an area of the Pb-5Sn solder of about 10% wherein the area extending from the end of the Pb-5Sn solder to the connection section. From such result, it has been found that the load due to thermal stress decreases with respect to the chip because of the flexible characteristic of the solder.

### COMPARATIVE EXAMPLE 2

In the comparative example 2, a composite foil having 20 μm thickness made of a Cu layer corresponding to the metal layer 110 and a Sn layer corresponding to the metal layer 120 without providing a constitution corresponding to the metal layer 100 is formed. The metallic foil constituted into such composite foil as described above is interposed between a power semiconductor element 1a on the side which has been metallized and a Cu lead frame 2, and die-mount-connection is conducted at 350° C. for holding 10 minutes in accordance with the same manner as that mentioned in the above-described examples 1 through 10 to fabricate a power semiconductor device 8a.

With respect to twenty power semiconductor packages each being obtained by the use of the power semiconductor element 8a thus fabricated, a temperature cycle test for 500 cycles of −55° C.(30 min.)/150° C.(30 min.) was implemented. As a result, cracks appeared in the chip and the Cu—Sn compound in a ratio of 6/20 as indicated in comparative example 2 of Table 2. This is because all the connection part formed with the use of the composite foil is made of the Cu—Sn compound, whereby the connection part becomes rigid and brittle, so that the thermal stress due to the temperature cycle cannot be buffered thereby.

Namely, it is considered that the metal layer 100 exerting stress buffering functions is not provided in the comparative example 2 unlike the present invention, so that the cracks appeared. This result may be a kind of such proof that the metal layer 100 exerting the stress buffering function in the present invention acts effectively for preventing the appearance of chip cracks, on the one hand.

### COMPARATIVE EXAMPLE 3

In the comparative example 3, a composite foil 7a containing a metal layer 100 exerting stress buffering function is not used unlike the present invention, but an Au-20Sn solder having 20 μm layer thickness is used to fabricate the power semiconductor device 8a having the constitution shown in FIG. 4. With respect to twenty power semiconductor packages each being obtained by the use of the power semiconductor device 8a thus fabricated, a temperature cycle test for 500 cycles of −55° C.(30 min.)/150° C.(30 min.) was implemented. As a result, cracks appeared in the chip and the connection part in a ratio of 5/20 as indicated in comparative example 3 of Table 2. In this respect, it is considered that since the Au-20Sn solder is a hard solder, the thermal stress due to temperature cycle cannot be buffered in the connection section, whereby the load increases with respect the chip.

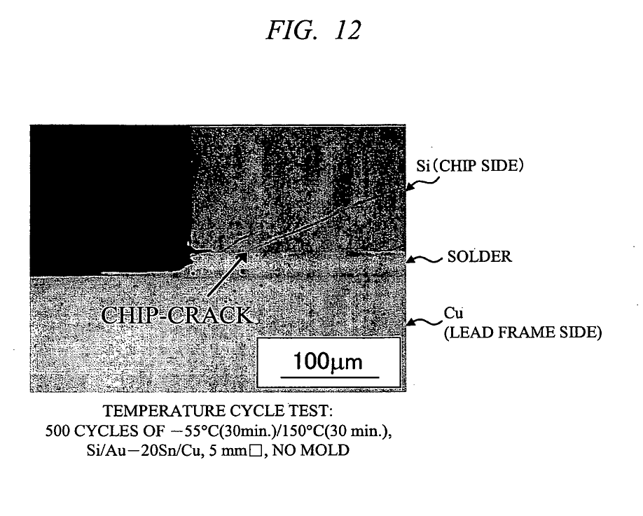

FIG. 12 shows an example of the chip cracks appeared. The case of FIG. 12 is in such that wherein a 5 mm square power semiconductor device 8a accompanied with no mold is die-mount-connected to a Cu lead frame with an Au-20Sn solder in 20 μm layer thickness at 350° C. for 10 minute holding time. Thereafter, the resulting product is subjected to temperature recycle test.

### Embodiment 6

In the embodiments 1 through 5, the connection layers 200 having the same constitutions and functioning as the stress buffering layers are formed on the semiconductor element side 1 and the side of the lead frame 2 of the metal layer 100 in the metal joint section 7 for connecting the semiconductor element 1 such as the power semiconductor element 1a with the substrate such as the lead frame 2 in the semiconductor device 8 such as the power semiconductor device 8a as shown in FIG. 5B.

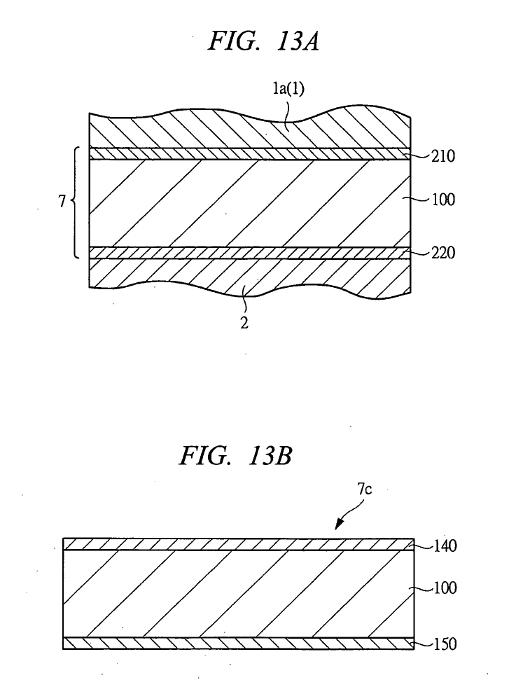

In the present embodiment, unlike the case of FIG. 5B, the case wherein a metal layer functioning as the stress buffering layer 100 is sandwiched in between a connection layer 210 and another connection layer 220 being different from one another in a metal joint section 7 as shown in FIG. 13A will be described. The constitution described in the present embodiment may be applied to the power semiconductor devices 8a and 8b the constitutions thereof are shown, for example, in FIGS. 4 and 11, respectively, described in the embodiments 1 through 5.

Namely, roughly speaking, the constitutions described in the embodiments 1 through 5 differ from the constitution which will be described hereunder in the present embodiment 6 in that those of the connection layers formed on the opposite sides of the metal layer 100 constituting the metal joint section 7 are the same as or different from one another in the above-described both embodiments to be compared with each other.

The semiconductor device 8 applied in the present embodiment is constituted into the power semiconductor device 8a as shown in FIG. 4. More specifically, in the power semiconductor device 8a, the semiconductor element 1 being the power semiconductor element 1a is die-mount-connected onto the lead frame 2 through the metal joint section 7. The metal joint section 7 is formed in such that a composite foil 7c for forming the joint section shown in FIG. 13B is placed on a die pad of the lead frame 2, furthermore, the power semiconductor device 8a is placed on the composite foil 7c, and they are heated while maintaining the existing condition.

The rear surface on the silicon (Si) side of the power semiconductor element 1a being in contact with the composite foil 7c is metallized with Ti/Ni/Au to assure the wettability. Also, the leas frame 2 is, for example, copper(Cu)-based material having good coefficient of thermal conductivity. The power semiconductor element 1a and the lead frame 2 having the constitution as mentioned above is joined by means of the metal joint section 7 which is formed by such a manner that the interposed composite foil 7c is heated at a predetermined temperature in the case of the die-mount-connection to be melted and solidified.

In the composite foil 7c for forming the metal joint section 7, a metal layer 140 on a high melting point side made of a Pb-free solder having a melting point of 260° C. or higher to 400° C. or lower and forming a connection layer 210 on the semiconductor element side 1 is provided on either side of the metal layer 100 having a high melting point of 260° C. or higher as shown schematically in FIG. 13B. On the other side of the metal layer 100, a metal layer 150 on a low melting point side made of a Pb-free solder forming a connection layer 220 on the side of the lead frame 2, having a melting point of 260° C. or higher to 400° C. or lower, and the melting point of which is lower than that of the high melting point Pb-free solder forming the metal layer 140 is provided.

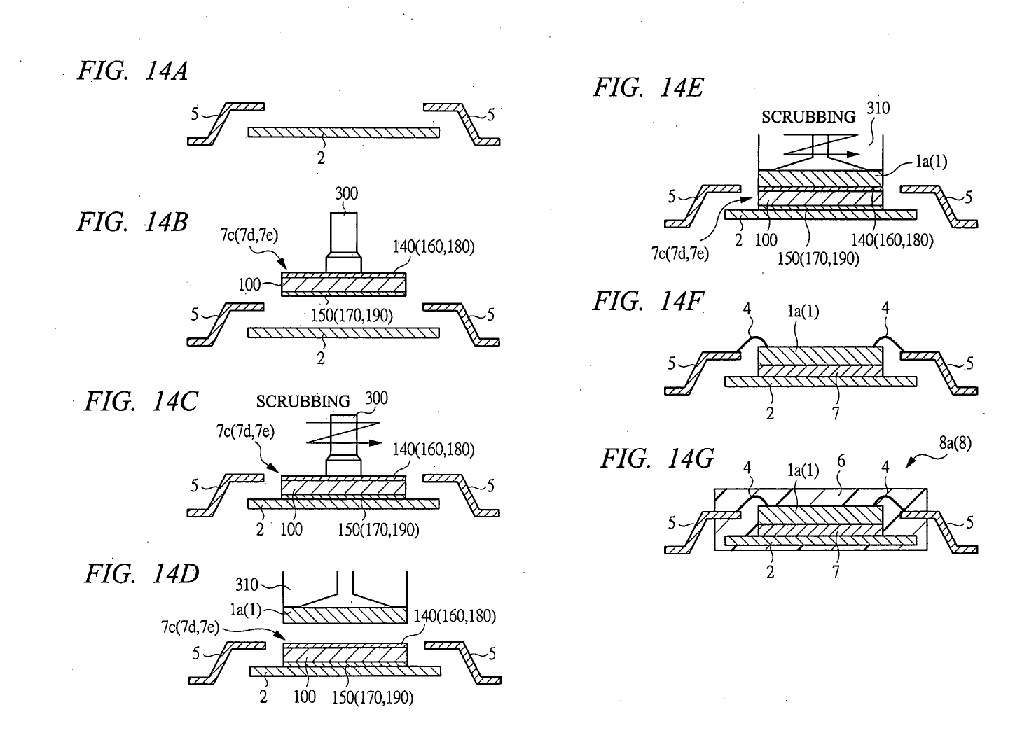

The composite foil 7c having the constitution as described above is used to metal-join the semiconductor element 1 constituted in the form of the power semiconductor element 1a to the substrate constituted in the form of the lead frame 2, whereby the semiconductor device constituted in the form of the power semiconductor device 8a shown in FIG. 4 is manufactured. Such manufacturing process will be described hereinbelow. The details of the process in the manufacturing method are schematically shown in FIGS. 14A to 14G.

Namely, as shown in FIGS. 14A and 14B, a metal layer 140 on a high melting point side of the composite foil 7c is held by a mounter 300, while a metal layer 150 on a low melting point side is supplied onto the lead frame 2 heated by a heater. In this case, the composite foil 7c is pressed and scrubbed at a temperature at which only the metal layer 150 on the low melting point side of the composite foil 7c is melted as shown in FIG. 14C, whereby the composite foil is supplied while allowing it to be closely in contact with the lead frame 2 and evacuating voids at the same time.

Thereafter, the composite foil 7c is heated up to a temperature at which the metal layer 140 on the high melting point side is melted, and the semiconductor element 1 as the power semiconductor element 1a the rear metallization of which is Ti/Ni/Au is supplied onto the metal layer 140 by means of a mounter 310 as shown in FIG. 14D. In this case, the power semiconductor element 1a is supplied while pressing and scrubbing it as shown in FIG. 14E, whereby wettability in the connection part is assured and voids are evacuated at the same time.

In the power semiconductor element 1a die-mount-connected by means of the metal joint section 7 which is made to have a high melting point, then, an electrode formed on the upper surface of the power semiconductor element 1a is bonded to leads 5 with the use of Au wires 4, respectively, as shown in FIG. 14F. Furthermore, the power semiconductor element 1a, the lead frame 2, the metal joint section 7, and the wires 4 are sealed by using an epoxy-based resin 6, whereby the semiconductor device 8 constituted in the form of the semiconductor device 8a is manufactured as shown in FIG. 14G.

In the semiconductor device 8 having the constitution as described above, compositions of the metal layers 100, 140, and 150 constituting the composite foil 7c are variously changed, and effectiveness in the constitutions of the present embodiment are verified. The results of the verification are shown in examples 20 to 23 of Table 2.

The composite foils 7c constituted in the conditions described in examples 20 to 23 of Table 2 are used to fabricate power semiconductor packages in accordance with the process as described above. With respect to twenty power semiconductor packages each in the respective examples, a temperature cycle test for 500 cycles of −55° C.(30 min.)/150° C.(30 min.) was implemented. Concerning the conditions of chip cracks, no chip crack appeared in all of the examples 20 to 23 as indicated in Table 2.

When the connection section of the metal joint section 7 is observed, cracks appeared in an area of Al of less than 5% wherein the area extending from the end of Al to the connection section in the case where the metal layer 100 of Al in examples 20, 22 and 23 functions to buffer thermal stress. On the other hand, when the connection section is observed in the case where the metal layer is a Cu/Invar alloy/Cu in example 21 having an intermediate thermal expansion coefficient of Si and Cu, no crack appeared on any of Si, in the metallic compounds, and in the Cu/Invar alloy/Cu. The thermal stress due to the temperature cycles is buffered by means of the metal layer 100 in Al and the Cu/Invar alloy/Cu. As a result, it is supposed that the appearance of chip cracks can be prevented.

Although there is not indicated in Table 2, the test, wherein the metal layers 100, 140, and 150 constituting the composite foil 7c are variously changed, was conducted by the present inventors. It has been found from the results obtained by the above-described test in combination with the results shown in examples 20 to 23 in Table 2 that the connection layer 210 formed on the semiconductor element side of the metal layer 100 having a function to act as a stress buffering layer is constituted by a Pb-free solder layer of Au—Sn-based alloys, Au—Ge-based alloys, Au—Si-based alloys, Zn—Al-based alloys, Zn—Al—Ge-based alloys, Bi, Bi—Ag-based alloys, Bi—Cu-based alloys, Bi—Ag—Cu-based alloys and the like alloys each having a melting point of 260° C. or higher to 400° C. or lower, while the connection layer 220 formed on the lead frame side of the metal layer 100 functioning as a stress buffering layer is made to have a constitution made of a Pb-free solder having a lower melting point than that of the connection layer 210 of 260° C. or higher to 400° C. or lower, whereby a die-mount-connection by which sufficient connection reliability can be assured is achieved without accompanying appearance of any chip crack by applying these Pb-free solders.

Moreover, the die-mount-connection wherein the composite foil 7c described in the present embodiment was effective in the case where the die-mount-connection is applied to the semiconductor device 8 such as the power semiconductor device 8b and the like having the strap type structure shown in FIG. 11.

### Embodiment 7

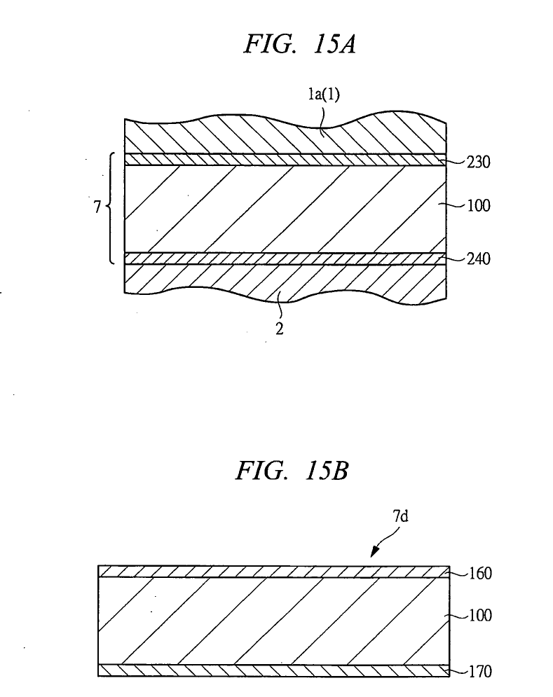

In the constitution described in the present embodiment 7, connection layers 230 and 240 which differ from one another are formed on the opposite sides of a metal layer 100 having a stress buffering function in a metal joint section 7 for joining a power semiconductor element 1a to a lead frame 2 being the substrate as shown in FIG. 15A as in the case of the above-described embodiment 6. The constitution of the present embodiment may be applied to the power semiconductor devices 8a and 8b having their constitutions shown, for example, in FIGS. 4 and 11, respectively, as in the case of the above-described embodiment 6.

Such metal joint section 7 as described above is formed by using a composite foil 7d as shown in FIG. 15B. The composite foil 7d is constituted in such that a metal layer 160 made of a Pb-free solder having a melting point of 260° C. or higher to 400° C. or lower is provided on the side where the metal layer 100 having functions of a stress buffering layer is to be connected with the semiconductor element 1, while a metal layer 170 made of a Pb-free solder having a melting point of 260° C. or lower which forms an intermetallic compound with a metal is provided on the side where the metal layer 100 is to be connected with the lead frame 2 as shown in FIG. 15B.

The semiconductor device 8 to which the present embodiment is to be applied is the one which is constituted in the form of the power semiconductor device 8a as shown, for example, in FIG. 4. In the power semiconductor device 8a, the semiconductor element 1 being the power semiconductor element 1a is die-mount-connected on the lead frame 2 through the metal joint section 7. The metal joint section 7 is formed by heating respective components in a condition wherein a composite foil 7d shown in FIG. 15B for forming the joint section is disposed on a die pad of the lead frame 2, and further the power semiconductor device 8a is disposed on the composite foil 7d.

For instance, the rear surface being in contact with the composite foil 7d on the silicon (Si) side of the power semiconductor element 1a is metallized with Ti/Ni/Au to assure the wettability. The lead frame 2 is, for example, made of a material of a copper (Cu)-based material having good coefficient of thermal conductivity. The power semiconductor element 1a and the lead frame 2 having such constitution as described above are joined with the metal joint section 7 formed by such a manner that the composite foil 7d interposed between the power semiconductor element 1a and the lead frame 2 is heated at a predetermined temperature to melt and solidify in the case of the die-mount-connection.

In the present embodiment, the power semiconductor device 8a having the constitution as described above can be manufactured as follows. Namely, as shown in FIGS. 14A and 14B, the side of the metal layer 160 of the composite foil is held by a mounter 300, while the side of the metal layer 170 is supplied onto the lead frame 2 heated by a heater. In this case, the composite foil is pressed and scrubbed at a temperature at which only the metal layer 170 on the low melting point side of the composite foil is melted as shown in FIG. 14C, whereby the composite foil is supplied while allowing it to be closely in contact with the lead frame 2 and evacuating voids at the same time.

It is to be noted that a reference numeral, e.g. 160 and the like relating to the composite foils 7d and 7e are indicated by putting it in parentheses so as not to confuse with those relating to the composite foil 7c in FIGS. 14A through 14G.

Thereafter, the composite foil 7d is heated up to a temperature at which the high melting point metal layer 160 side is melted, and the semiconductor element 1 its rear metallized with Ti/Ni/Au is supplied onto the metal layer by means of a mounter 310 as shown in FIG. 14D. In this case, the power semiconductor element 1 is supplied while pressing and scrubbing it as shown in FIG. 14E, whereby wetness is assured and voids are evacuated at the same time. After the die-mount-connection, the resulting product is held at 350° C. for 10 min., whereby the metal having a melting point of 260° C. or lower is allowed to react with the metal having a melting point of 260° C. or higher to make the connection layer to be an intermetallic compound so that a high melting point is attained in the resulting metallic compound.

In the power semiconductor element 1 die-mount-connected by means of the metal joint section 7 which is made to have a high melting point, then, an electrode formed on the upper surface of the power semiconductor element 1 is bonded to leads 5 using Au wires 4 as shown in FIG. 14F. Furthermore, the power semiconductor element 1a, the lead frame 2, the metal joint section 7, and the wire 4 are sealed by using an epoxy-based resin 6 as shown in FIG. 14G. As a result of applying the above-described process, the semiconductor device 8 is manufactured.

For the power semiconductor package thus fabricated in this manner, as indicated in examples 24 and 25 of Table 2, to twenty packages each of these conditions a temperature cycle test for 500 cycles of −55° C.(30 min.)/150° C.(30 min.) was implemented. Concerning the conditions in appearance of chip cracks, no chip crack appeared in all of the examples 24 and 25 as indicated in Table 2.

When the sectional view of the connection is observed, no crack appeared in any of Si, in the metallic compounds, and in the Cu/Invar alloy/Cu. It was found that the thermal stress due to the temperature cycles is buffered by means of the metal layer in the Cu/Invar alloy/Cu, so that the metal joint section 7 has sufficient connection reliability.

Although there is not indicated in Table 2, the test wherein the metal layers 100, 160, and 170 constituting the composite foil 7d are variously changed was conducted by the present inventors. It was found from the results obtained by the above-described test in combination with the results shown in examples 24 and 25 in Table 2 that the connection layer 230 formed on the semiconductor element side of the metal layer 100 having a function to act as a stress buffering layer is constituted by a Pb-free solder layer of such as Au—Sn-based alloys, Au—Ge-based alloys, Au—Si-based alloys, Zn—Al-based alloys, Zn—Al—Ge-based alloys, Bi, Bi—Ag-based alloys, Bi—Cu-based alloys, Bi—Ag—Cu-based alloys having a melting point of 260° C. or higher to 400° C. or lower, while the connection layer 240 formed on the lead frame side of the metal layer 100 functioning as a stress buffering layer is made to have a constitution made of an intermetallic compound having a melting point of 260° C. or higher which is formed by the reaction of one of Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based and the like Pb-free solders having a melting point of 260° C. or lower with at least one of metals of Cu, Ag, Ni, and Au at the time of die-mount-connection, whereby the die-mount-connection by which sufficient connection reliability can be assured is achieved without accompanying appearance of any chip crack by applying these Pb-free solders.

Moreover, the die-mount-connection wherein the composite foil 7d described in the present embodiment was effective in the case where the die-mount-connection is applied to the semiconductor device 8 such as the power semiconductor device 8b having the strap type structure shown in FIG. 11.

### Embodiment 8

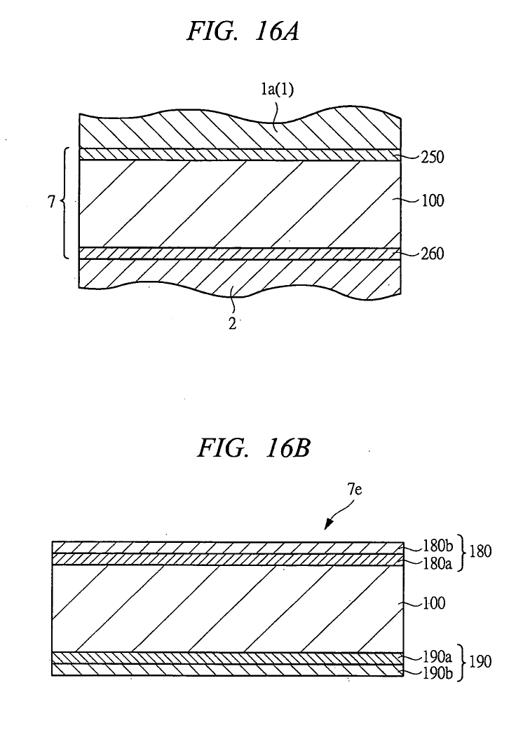

In the configuration described in a present embodiment 8, in a metal joint section 7 for joining a power semiconductor element 1a to a lead frame 2 being the substrate, as in the case of the above-described embodiment 6, connection layers 250 and 260 which differ from one another are formed sandwiching a metal layer 100 having a stress buffering function, as shown in FIG. 16A. The configuration of the present embodiment may be applied to the power semiconductor devices 8a and 8b having their configurations shown, for example, in FIGS. 4 and 11, respectively, as in the case of the above-described embodiment 6.

Such metal joint section 7 is formed by using a composite foil 7e as shown in FIG. 16B. The composite foil 7e is configured to have a metal layer 180 made of a Pb-free solder having a melting point of 260° C. or lower and a metal having a melting point of 260° C. or higher provided on the side where the metal layer 100 having stress buffering function a layer is connected with the semiconductor element, and a metal layer 190 made of a Pb-free solder having a melting point lower than that of the metal layer 180 and a metal having a melting point of 260° C. or higher provided on the side where the metal layer 100 is connected with the lead frame 2, as shown in FIG. 16B.

The metal layer 180 is configured, as shown in FIG. 16B, such that a metal layer 180a having a melting point of 260° C. or higher is provided on the upper surface of the metal layer 100, and a metal layer 180b made of a Pb-free solder having a melting point of 260° C. or lower is further laminated on the metal layer 180a. The metal layer 190 is also configured, as shown in FIG. 16B, such that a metal layer 190a having a melting point of 260° C. or higher is provided on the upper surface of the metal layer 100, and a metal layer 190b having a melting point of 260° C. or lower made of a Pb-free solder having a lower melting point than that of the Pb-free solder composing the metal layer 180b is further laminated on the metal layer 190a.

In the configuration shown in FIG. 16B, the laminated structure of the metal layer 180 is configured by the metal layers 180a and 180b, and the metal layer 190 is configured by the metal layers of 190a and 190b. However, the reason for the arrangement of such configuration is in that the metal layer 180a reacts with the metal layer 180b, while the metal layer 190a reacts with the metal layer 190b, respectively, at the time when the composite foil 7e is applied for die-mount-connection, whereby the intermetallic compounds each having a melting point of 260° C. or higher are obtained.

An example of such constitution of the composite foil 7e is exemplified, for example, in examples 26 and 27 in Table 2. In the case of example 26, the composite foil 7e is constituted by using, Cu as the metal layer 180a, Sn as the metal layer 180b, Al as the metal layer 100, Cu as the metal layer 190a, and In-48Sn as the metal layer 190b, respectively, wherein a total layer thickness of the metal layers 180a and 180b is 10 μm, a layer thickness of the metal layer 100 is 100 μm, and a total layer thickness of the metal layers 190a and 190b is 10 μm.

Similarly, in the case of example 27, the composite foil 7e is constituted by using, Ag as the metal layer 180a, Sn as the metal layer 180b, Al as the metal layer 100, Ag as the metal layer 190a, and Sn-9Zn as the metal layer 190b, respectively, wherein a total layer thickness of the metal layers 180a and 180b is 20 μm, a layer thickness of the metal layer 100 is 100 μm, and a total layer thickness of the metal layers 190a and 190b is 20 μm.

Furthermore, in the case where metal composition parts having substantially the same functions as that of the metal layers 180a and 190a are contained in the metal layer 100, the apparent constitution may be such that, although it is not shown, the metal layer 180 is made of only the metal layer 180b on the metal layer 100, while the metal layer 190 is made of only the metal layer 190b on the metal layer 100.

Examples of such constitution as described above are indicated in examples 28 to 30 of Table 2. Namely, in the case of example 28, the composite foil 7e is constituted by using, Sn as the metal layer 180b, Cu/Invar/Cu as the metal layer 100, and In-48Sn as the metal layer 190b, respectively, wherein a layer thickness of the metal layer 180b is 10 μm, a layer thickness of the metal layer 100 is 100 μm, and a layer thickness of the metal layer 190b is 10 μm. However, in this case, the Cu in the Cu/Invar/Cu has functions as that of the metal layers 180a and 190a shown in FIG. 16B.

Similarly, in the case of example 29, the composite foil 7e is constituted by using, Sn-3.5Ag as the metal layer 180b, Cu/Invar/Cu as the metal layer 100, and In-48Sn as the metal layer 190b, respectively, wherein a layer thickness of the metal layer 180b is 10 μm, a layer thickness of the metal layer 100 is 100 μm, and a layer thickness of the metal layer 190b is 10 μm. However, in this case, the Cu in the Cu/Invar/Cu functions to act as that of the metal layers 180a and 190a shown in FIG. 16B.

In the case of example 30, the composite foil 7e is constituted by using, Sn as the metal layer 180b, Cu/Invar/Cu as the metal layer 100, and Sn-9Zn as the metal layer 190b, respectively, wherein a layer thickness of the metal layer 180b is 10 μm, a layer thickness of the metal layer 100 is 100 μm, and a layer thickness of the metal layer 190b is 10 μm. However, in this case, the Cu in the Cu/Invar/Cu functions to act as that of the metal layers 180a and 190a shown in FIG. 16B.

The semiconductor device 8 to which the present embodiment is to be applied is constituted in the form of, for example, the power semiconductor device 8a as shown in FIG. 4. In the power semiconductor device 8a, the semiconductor element 1 being the power semiconductor element 1a is die-mount-connected onto the lead frame 2 interposing the metal joint section 7 therebetween. The metal joint section 7 is formed by heating respective components in a condition wherein a composite foil 7e shown in FIG. 16B for forming the joint section is disposed on a die pad of the lead frame 2, and further the power semiconductor device 8a is disposed on the composite foil 7e.

For instance, the rear surface being in contact with the composite foil 7e on the silicon (Si) side of the power semiconductor element 1a is metallized with Ti/Ni/Au to assure the wettability. In addition, the lead frame 2 is, for example, made of a material of a copper(Cu)-based material having a good coefficient of thermal conductivity. The power semiconductor element 1a and the lead frame 2 having such constitution as described above are joined to the metal joint section 7 formed by such a manner that the composite foil 7e interposed between the power semiconductor element 1a and the lead frame 2 is heated at a predetermined temperature to melt and solidify at the time of the die-mount-connection.

In the present embodiment, the power semiconductor device 8a having the constitution as described above can be manufactured as follows. That is, as shown in FIGS. 14A and 14B, a mounter 300 holds the side of the metal layer 180 where the melting point thereof is high of the composite foil, while the side of the metal layer 190 where the melting point thereof is low is supplied onto the lead frame 2 heated by a heater. At this time, the composite foil is pressed and scrubbed at a temperature at which only the metal layer 190 on the low melting point side of the composite foil is melted, as shown in FIG. 14C, whereby the composite foil is supplied while allowing it to be closely in contact with the lead frame 2 and evacuating voids at the same time.

Note that, a reference numeral, e.g. 180 and the like relating to the composite foils 7d and 7e are indicated by putting it in parentheses so as not to confuse with those relating to the composite foil 7c in FIGS. 14A through 14G.

Thereafter, the composite foil is heated up to a temperature at which the metal layer 180 on the high melting point side is melted, and the semiconductor element 1 its rear metallization is Ti/Ni/Au is supplied onto the metal layer by means of a mounter 310, as shown in FIG. 14D. In this case, the power semiconductor element 1 is supplied while pressing and scrubbing it as shown in FIG. 14E, whereby wettability is assured and voids are evacuated at the same time. After the die-mount-connection, the resulting product is held at 350° C. for 10 min., whereby the metal having a melting point of 260° C. or lower is allowed to react with the metal having a melting point of 260° C. or higher to make the connection layer to be an intermetallic compound so that a high melting point is attained in the resulting metallic compound.

In the power semiconductor element 1 die-mount-connected by means of the metal joint section 7 which is made to have a high melting point, then, an electrode formed on the upper surface of the power semiconductor element 1 is bonded to leads 5 using Au wires 4, respectively, as shown in FIG. 14F. Furthermore, the power semiconductor element 1a, the lead frame 2, the metal joint section 7, and the wires 4 are sealed by using an epoxy-based resin 6 as shown in FIG. 14G. As a result of applying the above-described process, the semiconductor device 8 is manufactured.

For the power semiconductor package thus fabricated in this manner, as indicated in examples 26 through 30 of Table 2, to twenty packages each of these conditions a temperature cycle test for 500 cycles of −55° C.(30 min.)/150° C.(30 min.) was implemented. Concerning the conditions in appearance of chip cracks, no chip crack appeared in all of the examples 26 through 30 as indicated in Table 2.

When the sectional view of the connection is observed, cracks are appeared in the Al area which is less than 5% from the edge of Al to the connection section. As a result, it has been found that the thermal stress due to the temperature cycles is buffered by means of the metal layer of Al, so that the metal joint section 7 has sufficient connection reliability.

Although there is not indicated in Table 2, the test wherein the metal layers 100, 180 (180a, 180b), and 190 (190a, 190b) constituting the composite foil 7e are variously changed was conducted by the present inventors. It was found from the results obtained by the above-described test in combination with the results shown in examples 29 through 30 in Table 2 that the connection layer 250 formed on the semiconductor element side of the metal layer 100 having a function as a stress buffering layer is made to have a constitution made of an intermetallic compound having a melting point of 260° C. or higher which is formed by the reaction of one of such as Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based Pb-free solders having a melting point of 260° C. or lower with at least one of metals of Cu, Ag, Ni, and Au at the time of die-mount-connection, while the connection layer 260 formed on the lead frame side of the metal layer 100 functioning as a stress buffering layer is made to have a constitution made of an intermetallic compound having a melting point of 260° C. or higher which is formed by the reaction of one of such as Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based Pb-free solders having a lower melting point than that of the Pb-free solder forming the connection layer 250 with at least one of metals of Cu, Ag, Ni, and Au at the time of die-mount-connection, whereby the die-mount-connection by which sufficient connection reliability can be assured is achieved without accompanying appearance of any chip crack by applying these Pb-free solders.

Moreover, the constitutions described in examples 31 and 32 of Table 2 were also effective for the composite foil 7e having the constitution shown in FIG. 16B. The constitution of example 31 is exemplified Cu is used as the metal layer 180a, Au-20Sn is used as the metal layer 180b, Al is used as the metal layer 100, Cu is used as the metal layer 190a, and Sn is used as the metal layer 190b, respectively. It is designed that a total layer thickness of the metal layers 180a and 180b is 20 μm, a layer thickness of the metal layer 100 is 100 μm, and a total layer thickness of the metal layers 190a and 190b is 20 μm.

The constitution of example 32 is exemplified such that Cu is used as the metal layer 180a, Bi is used as the metal layer 180b, Al is used as the metal layer 100, Cu is used as the metal layer 190a, and Sn is used as the metal layer 190b, respectively, wherein a total layer thickness of the metal layers 180a and 180b is 10 μm, a layer thickness of the metal layer 100 is 100 μm, and a total layer thickness of the metal layers 190a and 190b is 10 μm.

Furthermore, the die-mount-connection wherein the composite foil 7e is used described in the present embodiment was effective in the case where the die-mount-connection is applied to the semiconductor device 8 such as the power semiconductor device 8b having the strap type structure shown in FIG. 11.

### Embodiment 9

In the embodiments 1 through 8, it is described that the metal joint without accompanying appearance of any chip crack can be conducted by providing the stress buffering layer. In this respect, the present inventors studied points to keep in mind in the case of applying the composite foil 7a and the like used in the metal joining in view of manufacturing point of view. In the case of executing the constitutions shown in aforementioned embodiments 1 through 8, for example, any of the composite foils exemplified in Table 2 may be applied as described above. However, the metal joining with the use of such composite foil as described above is proposed for the first time by the present invention. Accordingly, it is very important for actually applying the invention of the present application that the points to keep in mind in the actual manufacturing stage are studied dissimilar the case where there are a number of long succession of practical knowledge in the actual manufacturing stage as in the conventional configurations.

In view of the fact that the present invention has been made for assuring connection reliability of a high degree, the present inventors studied factors for affecting connection reliability in the case of employing particularly the composite foil. As a result, it has been found that the connection reliability is remarkably affected with or without scrubbing in the case of supplying the composite foil at the time of die-mount-connection.

Table 3 indicates cases of examples 10 and 28 shown in Table 2 with respect to influences upon poor connection after the connection with or without scrubbing in the case of metal-joining with the use of the composite foil at the time of die-mount-connection.

TABLE 3

| | | | Pressurizing/ | | |
|---|---|---|---|---|---|
| | | Pressurizing/ | Scrubbing at | | Number of |
| | | Scrubbing at | Supplying | | Appearance |
| | Composition of | Supplying | Semiconductor | Connection | of Poor |
| No. | Die-Mount-Connection Part | Composite Foil | Element | Temperature | Connection |
| 1 | Sn/(Cu/Inver/Cu)/Sn = 10 μm/ | No | No | 400° C. | 10/20 |
| | 100 μm/10 μm | | | | |
| 2 | Sn/(Cu/Inver/Cu)/Sn = 10 μm/ | No | Yes | 400° C. | 3/20 |
| | 100 μm/10 μm | | | | |
| 3 | Sn/(Cu/Inver/Cu)/Sn = 10 μm/ | Yes | Yes | 400° C. | 0/20 |
| | 100 μm/10 μm | | | | |
| 4 | Sn/(Cu/Inver/Cu)/In—48Sn = 10 μm/ | Yes | Yes | 400° C. | 0/20 |
| | 100 μm/10 μm | | | | |

In the case of manufacturing a semiconductor package with the use of a composite foil, the procedure is such that, first the composite foil is supplied on a lead frame to join the composite foil to the lead frame, and then, a semiconductor element is supplied onto the composite foil joined to the lead frame to join the semiconductor element to the composite foil. In such procedure as described above, a timing for applying the scrubbing is considered to be in the case of supplying the composite foil onto the lead frame, or in the case of supplying the semiconductor element onto the composite foil joined onto the lead frame. The present inventors studied on influences in both the above-described cases with or without the scrubbing.

Table 3 indicates a condition with pressurizing/scrubbing, or a condition without pressurizing/scrubbing in the case of supplying the composite foil onto the lead frame (indicated by “Pressurizing/Scrubbing at supplying Composite Foil” in the table); and a condition with pressurizing/scrubbing, or a condition without pressurizing/scrubbing in the case of supplying the semiconductor element onto the composite foil joined onto the lead frame (indicated by “Pressurizing/Scrubbing at Supplying Semiconductor Element” in the table).

Table 3 indicates the number of appearance of poor connection after the connection in both the cases of examples 10 and 28 in Table 2. Here, such a condition that a ratio of unconnected part, i.e. the presence of voids and unwet parts observed by means of ultrasonic flaw detection is 20% or more is defined as the poor connection.

When no scrubbing is applied to both the cases of supplying the composite foil and the semiconductor element (indicated by No. 1 in the table) in the semiconductor package of example 10 containing a metal joint having an excellent constitution wherein no appearance of chip crack is observed, poor connections appeared in the half of the samples. In this respect, however, when pressurizing/scrubbing is applied in only the case of supplying the semiconductor element, the poor connections were remarkably reduced as indicated by No. 2 of Table 3. Nevertheless, an appearance of poor connection was confirmed with respect to a part of the samples. Accordingly, when the pressurizing/scrubbing is applied in both the cases of supplying the composite foil and the semiconductor element (indicated by No. 3 in the table), it was confirmed that no poor connection appeared.

Thus, as shown in the embodiments 1 through 5, it is desirable to apply at least pressurizing/scrubbing step to either case of supplying the composite foil or the case of supplying the semiconductor element in the die-mounting wherein the composite foil which is prepared by providing the metal layers having the same constitutions on the both sides of metal layer having stress buffering function is used. Besides, it has been confirmed that it is very desirable to apply the pressurizing/scrubbing step to both the cases of supplying the composite foil and supplying the semiconductor element.

The results as described above are also applicable for the case where the die-mounting wherein the composite foil which is prepared by providing the metal layers having different constitutions from one another on the both sides of the other metal layer having stress buffering function is applied as shown in the embodiments 6 through 8. In illustration of such results as described above, the number of appearance of poor connection is shown in the Table 3, in the constitution corresponding to example 28 of Table 2 wherein the pressurizing/scrubbing step is applied to both the cases of supplying the composite foil and supplying the semiconductor element. The number of appearance of poor connection was decreased as compared with the case where no pressurizing/scrubbing step was applied and the case where the pressurizing/scrubbing step was applied to either the case of supplying the composite foil or the case of supplying the semiconductor element.

From the above-described results, it has been confirmed that when a temperature stratum is provided in the connection layer on the front and rear surfaces of a composite foil and the pressurizing/scrubbing steps are applied to cases of supplying the composite foil and supplying the semiconductor element, the connectability and the void evacuatability can be improved.

In the foregoing, the invention made by the inventors of the present invention has been concretely described based on the embodiments. However, it is needless to say that the present invention is not limited to the foregoing embodiments and various modifications and alterations can be made within the scope of the present invention.

In other words, although the case where the invention is applied to the die-mount-connection for a power semiconductor device has been described as the exemplification, an applicable semiconductor device is not limited to such power semiconductor device, but they may be the ones other than the power semiconductor device as long as they are to be die-mount-connected. Examples of them include a diode for alternators, an IGBT substrate, a front-end module such as an RF module, a power module for automobiles.

In addition, in the above description, although such an example wherein a semiconductor package employing a power semiconductor device is reflow-mounted onto the substrate has been described, the invention may be applied to, for example, the case wherein an MCM (Multi Chip Module) configuration is used, as a matter of course.

In the above description, a laminated configuration wherein a metal layer 120 made of a metal having a low melting point of 260° C. or lower and a metal layer 110 made of a metal having a high melting point of 260° C. or higher are laminated on the metal layer 100 in such a manner that the low melting point metal layer 120 is positioned on the side of a material to be connected has been described. However, it may be modified such that a single layer having a constitution wherein the metal having a low melting point of 260° C. or lower exists mixedly with the metal having a high melting point of 260° C. or higher is applied within a range wherein wettability can be assured between the material to be connected thereto. For example, both the metals may be nested in a reticular pattern, or a row of the low melting point metal may be paralleled to a row of the high melting point metal in a staggered pattern. It is sufficient that a connection layer 200 obtained by the reaction of the above-described both components and having a high melting point of 260° C. or higher can be formed, as a result of heating both the components while maintaining a state wherein the wettability between the side of the material to be connected thereto is assured.

### INDUSTRIAL APPLICABILITY

The present invention can be applied effectively to the die-mount-connection for a semiconductor device represented by a power semiconductor.

1. A semiconductor device wherein a semiconductor element is die-mount-connected onto a lead frame by means of a metal joint, characterized in that the metal joint includes:
a stress buffering layer for buffering a thermal stress produced due to a thermal expansion coefficient difference between the lead frame and the semiconductor element;
a connection layer formed on the semiconductor element side of the stress buffering layer and connecting the stress buffering layer with the semiconductor element; and
another connection layer formed on the side of the lead frame of the stress buffering layer and connecting the stress buffering layer with the lead frame.

2. The semiconductor device according to claim 1, characterized in that the connection layer is a metal layer or an intermetallic compound layer having a melting point of 260° C. or higher; and the stress buffering layer is a metal layer having a thermal expansion coefficient ranging from the thermal expansion coefficient of the semiconductor element to the thermal expansion coefficient of the lead frame.

3. The semiconductor device according to claim 1, characterized in that the connection layer is a metal layer or an intermetallic compound layer having a melting point of 260° C. or higher; and the stress buffering layer is a metal layer having an yield stress of less than 100 MPa.

4. The semiconductor device according to claim 1, characterized in that the connection layer formed on the semiconductor element side of the stress buffering layer is made of a Pb-free solder layer of an Au—Sn-based alloy, an Au—Ge-based alloy, an Au—Si-based alloy, a Zn—Al-based alloy, a Zn—Al—Ge-based alloy, Bi, a Bi—Ag-based alloy, a Bi—Cu-based alloy, a Bi—Ag—Cu-based alloy or the like having a melting point of 260° C. or higher to 400° C. or lower; and
the connection layer formed on the side of the lead frame of the stress buffering layer is made of a Pb-free solder layer having a lower melting point than that of the connection layer formed on the semiconductor element side of the stress buffering layer of 260° C. or higher to 400° C. or lower.

5. The semiconductor device according to claim 1, characterized in that the connection layer formed on the semiconductor element side of the stress buffering layer is made of a Pb-free solder layer of an Au—Sn-based alloy, an Au—Ge-based alloy, an Au—Si-based alloy, a Zn—Al-based alloy, a Zn—Al—Ge-based alloy, Bi, a Bi—Ag-based alloy, a Bi—Cu-based alloy, a Bi—Ag—Cu-based alloy or the like having a melting point of 260° C. or higher to 400° C. or lower; and
the connection layer formed on the side of the lead frame of the stress buffering layer is made of an intermetallic compound layer having a melting point of 260° C. or higher and formed by the reaction of at least one of Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based and the like Pb-free solders with at least one metal of Cu, Ag, Ni, and Au in the case of the die-mount-connection.

6. The semiconductor device according to claim 1, characterized in that the connection layer formed on the semiconductor element side of the stress buffering layer is made of an intermetallic compound layer having a melting point of 260° C. or higher and formed by the reaction of at least one of Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based and the like Pb-free solders each having a melting point of 260° C. or lower with at least one metal of Cu, Ag, Ni, and Au in the case of the die-mount-connection; and
the connection layer formed on the side of the lead frame of the stress buffering layer is made of an intermetallic layer having a melting point of 260° C. or higher and formed by the reaction of at least one of Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, Bi—In-based and the like Pb-free solders each having a lower melting point than that of the Pb-free solder forming the connection layer formed on the semiconductor element side of the stress buffering layer with at least one metal of Cu, Ag, Ni, and Au in the case of the die-mount-connection.

7. A semiconductor device wherein a semiconductor element is die-mount-connected onto a lead frame by means of a metal joint, characterized in that:
the metal joint contains an unreacted high melting point metal which does not react in the case of the die-mount-connection; and
an intermetallic compound formed by the reaction in the case of joining the high melting point metal to the semiconductor element as well as joining the high melting point metal to the lead frame.

8. A semiconductor device having a semiconductor element, and a substrate connected to the semiconductor element, characterized in that:
the semiconductor element is connected with the substrate through a metal containing layer containing a metal and an intermetallic compound layer being thinner than the metal containing layer and including the metal component contained in the metal containing layer; and
the connection between the semiconductor element and the substrate does not melt even at the heat-resistant upper limit of the semiconductor device.

9. A semiconductor device having a semiconductor element, and a lead frame connected to the semiconductor element through a connection part, characterized in that:
the connection part has a metal containing layer containing a metal and an intermetallic compound layer being thinner than the metal containing layer and including the metal component contained in the metal containing layer; and
the connection part does not melt even at the heat-resistant upper limit of the semiconductor device.

10. A semiconductor device wherein a semiconductor element is die-mount-connected onto a lead frame, then, the resulting product is subjected to wire-bonding, and resin-molding, characterized in that:
the die-mount-connected part is composed successively of from the semiconductor element side, an intermetallic compound layer having a melting point of 260° C. or higher, a metallic compound layer having a melting point of 260° C. or higher, and another intermetallic compound layer having a melting point of 260° C. or higher in this order.

11. The semiconductor device according to claim 10, characterized in that the intermetallic compound layer is formed by the reaction of at least one of Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, and Bi—In-based Pb-free solders with at least one metal of Cu, Ag, Ni, and Au in the case of the die-mount-connection.

12. A semiconductor device wherein a semiconductor element is die-mount-connected onto a lead frame, then, the resulting product is subjected to wire-bonding, and resin-molding, characterized in that:
the die-mount-connected part is composed successively of from the semiconductor element side, a Pb-free solder layer having a melting point of 260° C. or higher to 400° C. or lower, a metallic compound layer having a melting point of 260° C. or higher, and another Pb-free solder layer having a melting point of 260° C. or higher to 400° C. or lower, in this order.

13. The semiconductor device according to claim 12, characterized in that the Pb-free solder layer having a melting point of 260° C. or higher to 400° C. or lower is made of at least any one of Au—Sn-based alloys, Au—Ge-based alloys, Au—Si-based alloys, Zn—Al-based alloys, Zn—Al—Ge-based alloys, Bi, Bi—Ag-based alloys, Bi—Cu-based alloy, and Bi—Ag—Cu-based alloys.

14. The semiconductor device according to claim 10, characterized in that the metal layer having a melting point of 260° C. or higher is made of at least one metal of Al, Mg, Ag, Zn, Cu, and Ni.

15. The semiconductor device according to claim 10, characterized in that the metal layer having a melting point of 260° C. or higher is made of at least one member of Cu/Invar alloy/Cu composite materials, Cu/Cu₂O composite materials, Cu—Mo alloys, Ti, Mo, and W.

16. A manufacturing method for a semiconductor device wherein a semiconductor element is die-mount-connected onto a lead frame by means of a metal joint, characterized by:
heating a composite foil to form a metal joint in a condition wherein the composite foil is interposed between the semiconductor element and the lead frame to from the metal joint;
the composite foil including a layer containing a metal having a melting point of 260° C. or lower and disposed on the semiconductor element side of a metal layer having a melting point of 260° C. or higher as well as another metal having a melting point of 260° C. or higher and disposed on the side of the lead frame of the metal layer, both the metals forming an intermetallic compound having a melting point of 260° C. or higher as a result of a reaction.

17. The manufacturing method for a semiconductor device according to claim 16, characterized in that:
the metal layer having a melting point of 260° C. or higher is formed from at least any one of Al, Mg, Ag, Zn, Cu, and Ni;
the metal having a melting point of 260° C. or lower and forming an intermetallic compound having a melting point of 260° C. or higher as a result of the reaction is at least one of Sn, In, Sn—Ag-based, Sn—Cu-based, Sn—Ag—Cu-based, Sn—Zn-based, Sn—Zn—Bi-based, Sn—In-based, In—Ag-based, In—Cu-based, Bi—Sn-based, and Bi—In-based Pb-free solders; and
the metal having a melting point of 260° C. or higher and forming an intermetallic compound having a melting point of 260° C. or higher as a result of the reaction is at least one metal of Cu, Ag, Ni, and Au.
